(19) United States
(12) Patent Application Publication
(10) Pub. No.: US 2026/0136993 A1
(43) Pub. Date: May 14, 2026

(54) SYSTEM ON INTEGRATED CIRCUIT STRUCTURE AND METHOD FOR FABRICATING THE SAME

(71) Applicant: Taiwan Semiconductor Manufacturing Company, Ltd., Hsinchu (TW)

(72) Inventors: Wen-Yun Wang, Taipei City (TW); Chao-Wen Shih, Hsinchu County (TW); Kuo-Chiang Ting, Hsinchu City (TW); Yen-Ming Chen, Hsin-Chu County (TW)

(73) Assignee: Taiwan Semiconductor Manufacturing Company, Ltd., Hsinchu (TW)

(21) Appl. No.: 18/948,322

(22) Filed: Nov. 14, 2024

(51) Int. Cl. H01L 25/10; H01L 23/00; H01L 23/31; H01L 23/498; H01L 25/00

(52) U.S. Cl. CPC H10W 90/00; H10W 70/60; H10W 70/6528; H10W 74/114; H10W 90/22; H10W 90/701

(57) ABSTRACT

A system on integrated circuit structure including first semiconductor dies, a first insulating encapsulant, a first redistribution circuit structure, a first bonding structure, and a second semiconductor die is provided. The first insulating encapsulant encapsulates the first semiconductor dies. The first redistribution circuit structure is disposed on the first semiconductor dies and the first insulating encapsulant. The first bonding structure is disposed on and electrically connected to the first redistribution circuit structure. The first bonding structure includes a first bonding dielectric layer and first bonding conductors embedded in the first bonding dielectric layer. The second semiconductor die includes a second bonding structure, the second bonding structure includes a second bonding dielectric layer and second bonding conductors embedded in the second bonding dielectric layer, wherein the first bonding dielectric layer is bonded with the second bonding dielectric layer, and the first bonding conductors are electrically connected to the second bonding conductors.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components, such as System on Integrated Circuits (SoIC) dies including semiconductor dies, become popular in some applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-7 are cross-sectional views schematically illustrating a process flow for fabricating singulated SoIC structures in accordance with the first embodiment of the present disclosure.

FIGS. 1-4 and FIGS. 8-9 are cross-sectional views schematically illustrating a process flow for fabricating singulated SoIC structures in accordance with the second embodiment of the present disclosure.

FIGS. 10-17 are cross-sectional views schematically illustrating a process flow for fabricating singulated SoIC structures in accordance with the third embodiment of the present disclosure.

FIGS. 10-15 and FIGS. 18-19 are cross-sectional views schematically illustrating a process flow for fabricating singulated SoIC structures in accordance with the fourth embodiment of the present disclosure.

FIGS. 20A through 20N are cross-sectional views schematically illustrating a process flow for fabricating integrated fan-out package structures of the SoIC structure shown in FIG. 7 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Various embodiments of SoIC structures or SoIC dies are discussed in the followings. To reduce the number of the bonding process performed during the fabrication of the SoIC structures, at least one redistribution circuit structure is utilized to vertically communicate semiconductor dies arranged in different tiers as well as horizontally communicate semiconductor dies arranged in the same tier. The variations of the embodiments are also discussed in the followings. Throughout the various views and illustrative embodiments, like reference numbers are used to designate like elements.

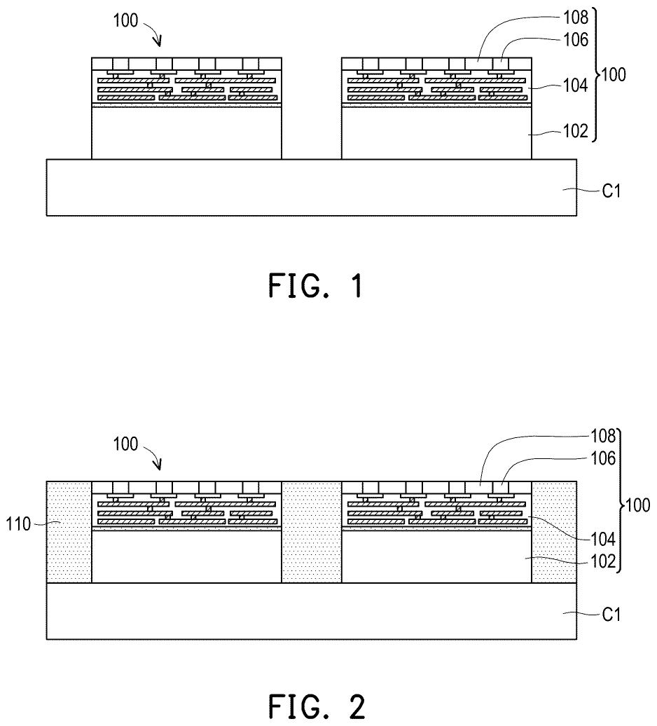

FIGS. 1-7 are cross-sectional views schematically illustrating a process flow for fabricating singulated SoIC structures in accordance with the first embodiment of the present disclosure.

Referring to FIG. 1, semiconductor dies 100 are provided. The semiconductor dies 100 are picked-up, placed on and bonded to a carrier C1 through a chip-to-wafer bonding process such that the semiconductor dies 100 are in contact with the carrier C1. The carrier C1 may be a semiconductor wafer, a glass substrate or other suitable substrates. The semiconductor dies 100 may be logic dies, System-on-Chip (SoC) dies or other suitable semiconductor dies with predetermined functions. The number of the semiconductor dies 100 is not limited although two semiconductor dies 100 are illustrated in FIG. 1. The semiconductor dies 100 may be arranged on the carrier C1 in a side-by-side manner. The semiconductor dies 100 are laterally spaced apart from each other by a gap. In some embodiments, the semiconductor dies 100 are placed on and bonded to the top surface of the carrier C1 through die attachment films (DAF). The die attachment films may be adhesive films sandwiched between the carrier C1 and the semiconductor dies 100. For example, die attachment films includes epoxy films, silicone films, other suitable adhesive layers or combinations thereof.

In some embodiments, the semiconductor dies 100 are placed on and bonded to the top surface of the carrier C1 in a face-up manner, wherein active surfaces of the semiconductor dies 100 face up, while rear surfaces of the semiconductor dies 100 are attached to the top surface of the carrier C1. The rear surfaces of the semiconductor dies 100 is between the carrier C1 and the active surfaces of the semiconductor dies. Each of the semiconductor dies 100 attached to the carrier C1 may perform the same function or different functions.

The semiconductor dies 100 may each include a substrate 102 (e.g., a semiconductor substrate), an interconnect structure 104, conductive pillars 106, and a protection layer 108. The substrate 102 of the semiconductor dies 100 may include a crystalline silicon substrate. The substrate 102 may include various doped regions depending on design requirements (e.g., p-type substrate or n-type substrate). The doped regions may be doped with p-type or n-type dopants. The doped regions may be doped with p-type dopants, such as boron or BF₂; n-type dopants, such as phosphorus or arsenic; and/or combinations thereof. In some embodiments, the doped regions are configured for n-type Fin-type Field Effect Transistors (FinFETs) and/or p-type FinFETs. In some other embodiments, the doped regions are configured for n-type Gate-All-Around Field Effect Transistors (GAAFETs) and/or p-type GAAFETs. In some alternative embodiments, the substrate 102 is made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The interconnect structure 104 is disposed on and electrically connected to semiconductor devices (e.g., FinFETs or GAAFETs) formed in the substrate 102. The interconnect structure 104 may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs or GAAFETs) formed in the substrate 102. The material of the one or more dielectric layers may include silicon oxide (SiOₓ, where x>0), silicon nitride (SiNₓ, where x>0), silicon oxynitirde (SiOₓN_{y}, where x>0 and y >0) or other suitable dielectric material. The interconnect wirings may include metallic wirings. For example, the interconnect wirings include copper wirings, copper pads, aluminum pads or combinations thereof.

The conductive pillars 106 are disposed on the interconnect structure 104. The conductive pillars 106 are electrically connected to the interconnect wirings of the interconnect structure 104. The conductive pillars 106 may be copper pillars or other suitable pillars with preferable conductivity. The protection layer 108 is disposed on the interconnect structure 104 and covers the conductive pillars 106. The thickness of the protection layer 108 may be greater than the height of the conductive pillars 106. At this stage, the conductive pillars 106 of the semiconductor dies 100 are well covered and protected by the protection layer 108.

Referring to FIG. 2, an insulating encapsulant 110 is formed on the carrier C1 to laterally encapsulate the semiconductor dies 100. An insulating encapsulation material may be a molding compound (e.g., epoxy or other suitable resin) formed through an over-molding process. The insulating encapsulation material not only fills the gaps between the neighboring semiconductor dies 100, but also covers the top surfaces of the semiconductor dies 100, wherein the top surface of the insulating encapsulation material is higher than the top surfaces of the semiconductor dies 100. Then, a planarization such as a Chemical Mechanical Polish (CMP) process and/or a mechanical grinding process is performed to partially remove the insulating encapsulation material until the conductive pillars 106 are exposed. After the insulating encapsulation material is partially removed, the insulating encapsulant 110 is formed to laterally encapsulate the semiconductor dies 100. Due to the planarization, the top surfaces of the semiconductor dies 100 substantially level with the top surface of the insulating encapsulant 110 within process variations. In the illustrated exemplary embodiments, the planarization is performed until the conductive pillars 106 of the semiconductor dies 100 are exposed.

As shown in FIG. 2, the insulating encapsulant 110 may fill the gap between the semiconductor dies 100. Furthermore, the insulating encapsulant 110 is in contact with sidewalls of the semiconductor dies 100. For example, the insulating encapsulant 110 is in contact with sidewalls of the substrate 102, sidewalls of the interconnect structure 104, and sidewalls of the protection layer 108. The conductive pillars 106 are laterally spaced apart from the insulating encapsulant 110 by the protection layer 108. The thickness of the encapsulation portion 110 is substantially equal to the thickness of the semiconductor dies 100.

During the above-mentioned planarization process, the protection layer 108 is partially removed to reveal the top surfaces of the conductive pillars 106. At this stage, the top surfaces of the conductive pillars 106 substantially level with the top surface of the protection layer 108 and the top surface of the insulating encapsulant 110 within process variations.

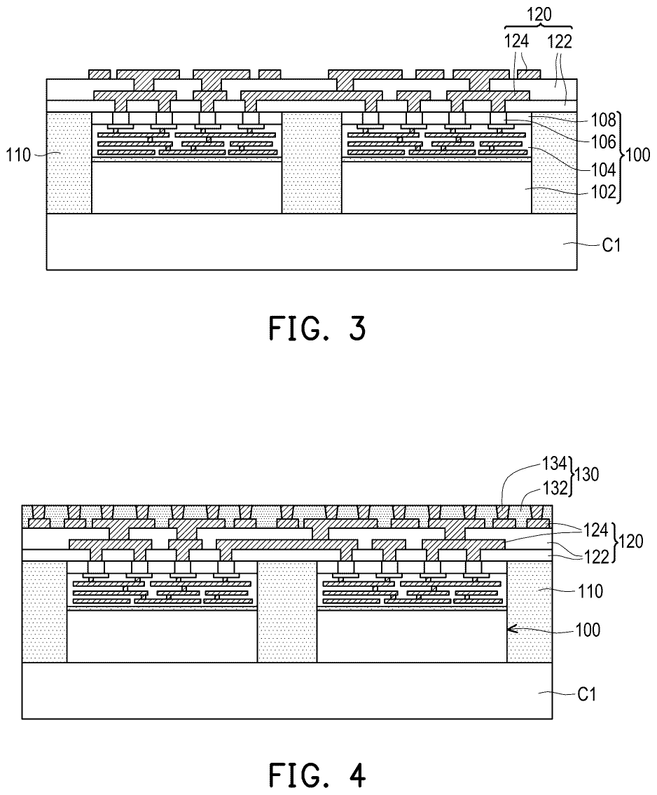

Referring to FIG. 3, a redistribution circuit structure 120 including dielectric layers 122 and redistribution wirings 124 embedded in the dielectric layers 122 is formed. The redistribution circuit structure 120 is deposited over the semiconductor dies 100 and the insulating encapsulant 110 such that the semiconductor dies 100 and the insulating encapsulant 110 are between the redistribution circuit structure 120 and the carrier C1. The redistribution wirings 124 are electrically connected to the underlying conducitve pillars 106 of the semiconductor dies 100. As shown in FIG. 3, the dielectric layers 122 may be formed of a polymer, which may also be a photo-sensitive material such as polybenzoxazole (PBO), polyimide, benzocyclobutene (BCB), or the like, which may be easily patterned using a photolithography process followed by an etch process. In some other embodiments, the dielectric layers 122 are formed of a nitride such as silicon nitride, an oxide such as silicon oxide, PhosphoSilicate Glass (PSG), BoroSilicate Glass (BSG), Boron-doped PhosphoSilicate Glass (BPSG), or the like. The redistribution wirings 124 are formed over or between the dielectric layers 122. The formation of the redistribution wirings 124 may include forming a seed layer (not shown) over the dielectric layers 122, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 124 as shown in FIG. 3. In accordance with some embodiments, the seed layer includes a titanium layer and a copper layer over the titanium layer. The seed layer may be formed using, for example, Physical Vapor Deposition (PVD). FIG. 3 and the subsequent figures illustrate a multi-layered redistribution circuit structure 120 including two layers of redistribution wirings 124 for illustrative purposes and some embodiments may have a single layered redistribution wirings or more than two layers of redistribution wirings by repeating the process discussed above.

Referring to FIG. 4, a bonding structure 130 is formed on the redistribution circuit structure 120. The bonding structure 130 may include a bonding dielectric layer 132 and bonding conductors 134 embedded in the bonding dielectric layer 132. The material of the bonding dielectric layer 132 may be or include silicon oxide (SiOₓ, where x>0), silicon nitride (SiNₓ, where x>0), silicon oxynitirde (SiOₓN_{y}, where x>0 and y >0) or other suitable dielectric material, and the bonding conductors 134 may be or include conductive vias (e.g., copper vias), conductive pads (e.g., copper pads) or combinations thereof. The bonding structure 130 may be formed by depositing a dielectric material through a chemical vapor deposition (CVD) process (e.g., a plasma enhanced CVD process or other suitable process); patterning the dielectric material to form the bonding dielectric layer 132 including openings or through holes for revealing the underlying redistribution wirings 124; and filling conductive material in the openings or through holes defined in the bonding dielectric layer 132 to form the bonding conductors 134 embedded in the bonding dielectric layer 132. As illustrated in FIG. 4, the bonding conductors 134 of the bonding structure 130 are electrically connected to the semiconductor dies 100 through the redistribution circuit structure 120.

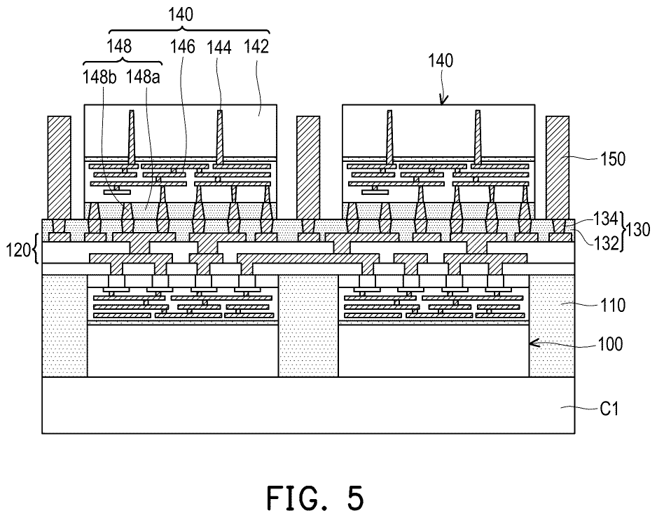

Referring to FIG. 5, semiconductor dies 140 are provided and placed on the bonding structure 130. The semiconductor dies 140 may be logic dies, System-on-Chip (SoC) dies or other suitable semiconductor dies. The semiconductor dies 140 may each includes a substrate 142 (e.g., a semiconductor substrate), through semiconductor vias 144 embedded in the substrate 142, an interconnect structure 146 disposed on the substrate 142, and a bonding structure 148 disposed on the interconnect structure 146. The through semiconductor vias 144 are electrically connected to the interconnect structure 146. The substrate 142 may include a crystalline silicon substrate. The substrate 142 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. In some embodiments, the doped regions are configured for n-type Fin-type Field Effect Transistors (FinFETs) and/or p-type FinFETs. In some other embodiments, the doped regions are configured for n-type Gate-All-Around Field Effect Transistors (GAAFETs) and/or p-type GAAFETs. In some alternative embodiments, the substrate 142 may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through semiconductor vias 144 may be formed by forming recesses in the substrate 142 by, for example, etching, milling, laser techniques, a combination thereof, and/or the like. A thin barrier layer may be conformally deposited over the front side of the substrate 142 and in the openings, such as by chemical vapor deposition (CVD), atomic layer deposition (ALD), physical vapor deposition (PVD), thermal oxidation, a combination thereof, and/or the like. The barrier layer may include a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 142 by, for example, chemical mechanical polishing. Thus, in some embodiments, the through semiconductor vias 144 may include a conductive material and a thin barrier layer between the conductive material and the substrate 142. At this stage, the through semiconductor vias 144 are buried in the substrate 142, and the through semiconductor vias 144 are not revealed from the rear surface of the substrate 142.

The interconnect structure 146 may include one or more dielectric layers (for example, one or more interlayered dielectric (ILD) layers, intermetal dielectric (IMD) layers, or the like) and interconnect wirings embedded in the one or more dielectric layers, and the interconnect wirings are electrically connected to the semiconductor devices (e.g., FinFETs or GAAFETs) formed in the substrate 142 and/or the through semiconductor vias 144. The material of the one or more dielectric layers may include silicon oxide (SiOₓ, where x>0), silicon nitride (SiNₓ, where x>0), silicon oxynitirde (SiOₓN_{y}, where x>0 and y >0) or other suitable dielectric material. The interconnect wirings may include metallic wirings. For example, the interconnect wirings include copper wirings, copper pads, aluminum pads or combinations thereof. In some embodiments, the through semiconductor vias 144 may extend through one or more layers of the interconnect structure 146 and into the substrate 142.

The bonding structure 148 may include a bonding dielectric layer 148a and bonding conductors 148b embedded in the bonding dielectric layer 148a. The material of the bonding dielectric layer 148a may be silicon oxide (SiOₓ, where x>0), silicon nitride (SiNₓ, where x>0), silicon oxynitirde (SiOₓN_{y}, where x>0 and y >0) or other suitable dielectric material, and the bonding conductors 148b may be conductive vias (e.g., copper vias), conductive pads (e.g., copper pads) or combinations thereof. The bonding structure 148 may be formed by depositing a dielectric material through a chemical vapor deposition (CVD) process (e.g., a plasma enhanced CVD process or other suitable process); patterning the dielectric material to form the bonding dielectric layer 148a including openings or through holes; and filling conductive material in the openings or through holes defined in the bonding dielectric layer 148a to form the bonding conductors 148b embedded in the bonding dielectric layer 148a.

A bonding process is performed to bond the bonding structures 148 of the semiconductor dies 140 with the underlying bonding structure 130. In some embodiments, the bonding process may be a bonding process that includes dielectric-to-dielectric bonding and metal-to-metal bonding. After performing the above-mentioned bonding process, a dielectric-to-dielectric bonding interface is formed between the bonding dielectric layer 132 and the bonding dielectric layer 148a, and metal-to-metal bonding interfaces are formed between the bonding conductors 134 and bonding conductors 148b. In some other embodiments, the bonding process may be a direct bonding process.

As illustrated in FIG. 5, conductive through-vias 150 may be formed on the bonding structure 130. The conductive through-vias 150 are electrically connected to the bonding conductors 134 of the bonding structure 130. The conductive through-vias 150 may be formed through plating process or other suitable deposition process. In some embodiments, the conductive through-vias 150 are formed prior to performing the pick-up and place process of the semiconductor dies 140. In the embodiment where the conductive through-vias 150 are formed prior to performing the pick-up and place process of the semiconductor dies 140, the thickness of the semiconductor dies 140 is greater than the height of the conductive through-vias 150, as shown in FIG. 5. In some alternative embodiments, the conductive through-vias 150 are formed after bonding the semiconductor dies 140 with the bonding structure 130. In the embodiment where the conductive through-vias 150 are formed after performing the pick-up and place process of the semiconductor dies 140, the height of the conductive through-vias is greater than the thickness of the semiconductor dies, not shown in Figures. FIG. 5 and the subsequent figures illustrate three conductive through-vias 150 for illustrative purposes and some embodiments may have less than or more than three conductive through-vias 150.

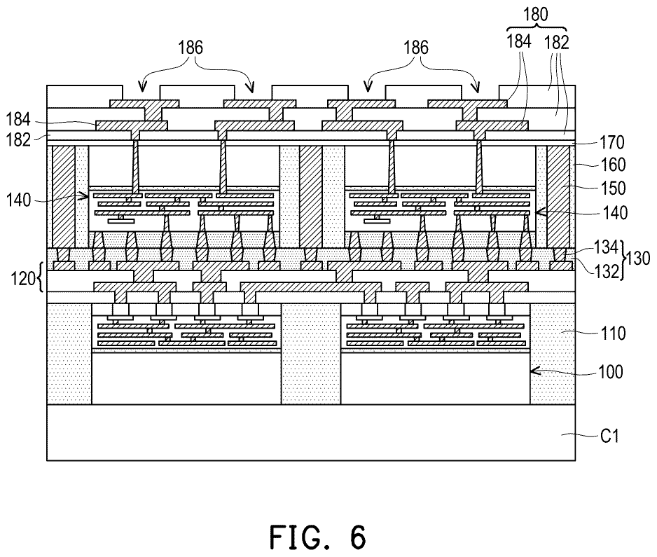

Referring to FIG. 6, an insulating encapsulant 160 is formed on the bonding structure 130 to laterally encapsulate the semiconductor dies 140 and the conductive through-vias 150. An insulating encapsulation material may be a molding compound (e.g., epoxy or other suitable resin) formed through an over-molding process. The insulating encapsulation material fills the gaps between the neighboring semiconductor dies 140 and the gaps between the semiconductor dies 140 and the conductive through-vias 150. The insulating encapsulation material covers the top surfaces of the semiconductor dies 140 and the conductive through-vias 150, wherein the top surface of the insulating encapsulation material is higher than the top surfaces of the semiconductor dies 140 and the top surfaces of the conductive through-vias 150. Then, a planarization such as a CMP process and/or a mechanical grinding process is performed to partially remove the insulating encapsulation material until the conductive through-vias 150 are exposed. After the insulating encapsulation material is partially removed, the insulating encapsulant 160 is formed to laterally encapsulate the semiconductor dies 140 and the conductive through-vias 150. Due to the planarization, the top surfaces of the semiconductor dies 140 and the top surfaces of the conductive through-vias 150 substantially level with the top surface of the insulating encapsulant 160 within process variations. In the illustrated exemplary embodiments, the planarization is performed until the through semiconductor vias 144 of the semiconductor dies 140 and the conductive through-vias 150 are exposed.

As shown in FIG. 6, the insulating encapsulant 160 is in contact with sidewalls of the semiconductor dies 140 and sidewalls of the conductive through-vias 150. For example, the insulating encapsulant 160 is in contact with sidewalls of the substrate 142, sidewalls of the interconnect structure 146, and sidewalls of the bonding structure 148. The through semiconductor vias 144 are laterally spaced apart from the insulating encapsulant 160 by the substrate 142. The thickness of the encapsulation portion 160 is substantially equal to the thickness of the semiconductor dies 140 and the height of the conductive through-vias 150. During the above-mentioned planarization process, the substrates 142 of the semiconductor dies 140 are partially removed to reveal ends of the through semiconductor vias 144 and the conductive through-vias 150. At this stage, the revealed ends of the through semiconductor vias 144 protrude from the rear surface of the substrate 142, and the top surfaces of the conductive through-vias 150 substantially level with the top surface of the insulating encapsulant 160 within process variations.

After forming the insulating encapsulant 160, a planarization layer 170 is formed on the rear surface of the substrate 142 to laterally encapsulate sidewalls of the revealed ends of the through semiconductor vias 144. The planarization layer 170 may be formed by a deposition process followed by a CMP process. The planarization layer 170 may be made of silicon nitride or other suitable dielectric materials.

As illustrated in FIG. 6, a redistribution circuit structure 180 including dielectric layers 182 and redistribution wirings 184 embedded in the dielectric layers 182 is formed on the planarization layer 170. In some embodiments, the planarization layer 170 is considered as a part of the redistribution circuit structure 180. The redistribution circuit structure 180 is deposited over the semiconductor dies 140, the conductive through-vias 150 and the insulating encapsulant 160 such that the semiconductor dies 140, the conductive through-vias 150 and the insulating encapsulant 160 are between the bonding structure 130 and the redistribution circuit structure 180. The redistribution wirings 184 are electrically connected to the underlying through semiconductor vias 144 of the semiconductor dies 140 as well as the underlying conductive through-vias 150. As shown in FIG. 6, the dielectric layers 182 may be formed of a polymer, which may also be a photo-sensitive material such as PBO, polyimide, BCB, or the like, which may be easily patterned using a photolithography process followed by an etch process. In some other embodiments, the dielectric layers 182 are formed of a nitride such as silicon nitride, an oxide such as silicon oxide, PSG, BSG, BPSG, or the like. The redistribution wirings 184 are formed over or between the dielectric layers 182. The formation of the redistribution wirings 184 may include forming a seed layer (not shown) over the dielectric layers 182, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 184 as shown in FIG. 6. In accordance with some embodiments, the seed layer includes a titanium layer and a copper layer over the titanium layer. The seed layer may be formed using, for example, Physical Vapor Deposition (PVD). FIG. 6 and the subsequent figures illustrate a multi-layered redistribution circuit structure 180 including two layers of redistribution wirings 184 for illustrative purposes and some embodiments may have a single layered redistribution wirings or more than two layers of redistribution wirings by repeating the process discussed above.

The topmost dielectric layer 182 of the redistribution circuit structure 180 is then patterned to form openings 186 therein through, for example, a photolithography process followed by an etch process. Hence, portions of the redistribution wirings 182 are exposed through the openings 186 in the topmost dielectric layer 182.

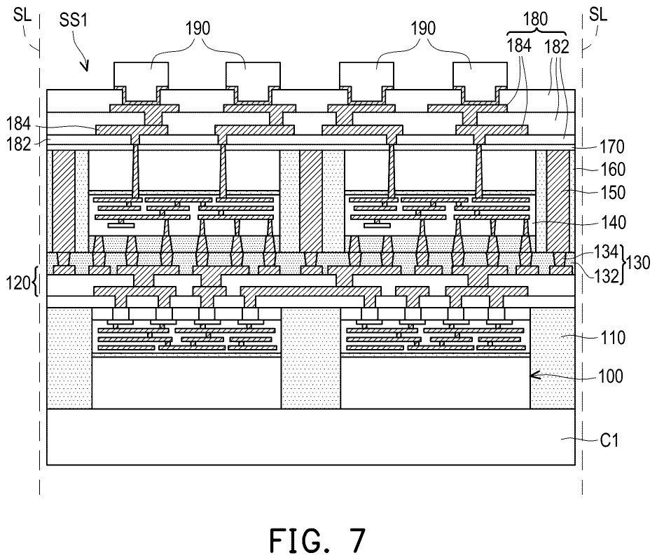

Referring to FIG. 6 and FIG. 7, after forming the redistribution circuit structure 180 over the semiconductor dies 140, the conductive through-vias 150 and the insulating encapsulant 160, conductive terminals 190 are formed on the redistribution circuit structure 180 and electrically connected to the redistribution wirings 184 of the redistribution circuit structure 180 through the openings 186 defined in the topmost dielectric layer 182. In some embodiments, the conductive terminals 190 are formed by plating. The plating of the conductive terminals 190 may include forming a blanket seed layer (not shown) over the dielectric layer 182 and extending into the openings 186 shown in FIG. 6, forming and patterning a photoresist (not shown), and plating the conductive terminals 190 on the portions of the seed layer that are exposed by openings defined in the photoresist. The photoresist and the portions of the seed layer that are covered by the photoresist are then removed. The material of the conductive terminals 190 may include copper, aluminum, or the like. The conductive terminals 190 may have the shape of rods. The top-view shapes of the conductive through-vias 190 may be circles, rectangles, squares, hexagons, or the like. In some embodiments, a reflow process may be performed to re-shape the profile of the conductive terminals 190.

As illustrated in FIG. 7, a singulation process (e.g., a wafer sawing process) is performed along scribe lines SL such that singulated SoIC structures SS1 are obtained. The singulated SoIC structure SS1 shown in FIG. 7 includes first semiconductor dies 100, a first insulating encapsulant 110, a first redistribution circuit structure 120, a first bonding structure 130 and second semiconductor dies 140. The first insulating encapsulant 110 laterally encapsulates the first semiconductor dies 100. The first redistribution circuit structure 120 is disposed on the first semiconductor dies 100 and the first insulating encapsulant 110. The first bonding structure 130 is disposed on and electrically connected to the first redistribution circuit structure 120, wherein the first bonding structure 130 includes a first bonding dielectric layer 132 and first bonding conductors 134 embedded in the first bonding dielectric layer 132. The second semiconductor dies 140 each includes a second bonding structure 148, the second bonding structure 148 includes a second bonding dielectric layer 148a and second bonding conductors 148b embedded in the second bonding dielectric layer 148a, wherein the first bonding dielectric layer 132 is bonded with the second bonding dielectric layer 148a, and the first bonding conductors 134 are electrically connected to the second bonding conductors 148b. The sidewalls of the first insulating encapsulant 110 may substantially align with sidewalls of the first bonding structure 130 and sidewalls of the first redistribution circuit structure 120. The first bonding structure 130 is between the first redistribution circuit structure 120 and the second semiconductor dies 140. The SoIC structure SS1 may further include a second insulating encapsulant 160 and a second redistribution circuit structure 180, wherein the second insulating encapsulant 160 is disposed on the first bonding structure 130 and laterally encapsulates the second semiconductor dies 140; and wherein the second redistribution circuit structure 180 is disposed on the second semiconductor dies 140 and the second insulating encapsulant 160, and second redistribution circuit structure 180 is electrically connected to the second semiconductor dies 140. In some embodiments, the second semiconductor dies 140 each includes through semiconductor vias 144 electrically connected to the first redistribution circuit structure 120 and the second redistribution circuit structure 180. The carrier C1 may be removed after performing the singulation process along the scribe lines SL.

As illustrated in FIG. 7, the first redistribution circuit structure 120 and the bonding structure 130 are disposed at a first side of the second semiconductor dies 140, the second redistribution circuit structure 180 is disposed at a second side of the second semiconductor dies 140, and the second side is opposite to the first side. In other words, the first redistribution circuit structure 120 and the second redistribution circuit structure 180 are disposed at opposite sides of the second semiconductor dies 140. The first redistribution circuit structure 120 is spaced apart from the second semiconductor dies 140 by the first bonding structure 130, and the second redistribution circuit structure 180 (i.e., the planarization layer 170 of the second redistribution circuit structure 180) is in directly contact with the second semiconductor dies 140. Furthermore, the first redistribution circuit structure 120 and the bonding structure 130 are disposed between the second semiconductor dies 140 and the underlying first semiconductor dies 100.

The first semiconductor dies 100 may communicate with each other by the first redistribution circuit structure 120, and the second semiconductor dies 140 may communicate with each other by the first redistribution circuit structure 120, the first bonding structure 130 and/or the second redistribution circuit structure 180. Furthermore, the first semiconductor dies 100 may communicate with the second semiconductor dies 140 by the first redistribution circuit structure 120, the first bonding structure 130 and the second redistribution circuit structure 180. Electrical connection and communication between every semiconductor dies (i.e., the first semiconductor dies 100 and the second semiconductor dies 140) in the SoIC structure SS1 can be achieved by the first redistribution circuit structure 120, the first bonding structure 130 and the second redistribution circuit structure 180.

FIGS. 1-4 and FIGS. 8-9 are cross-sectional views schematically illustrating a process flow for fabricating singulated SoIC structures in accordance with the second embodiment of the present disclosure.

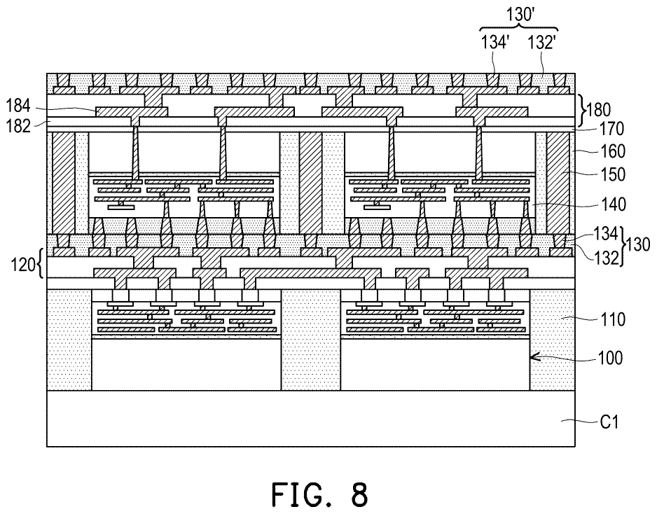

Referring to FIG. 8, semiconductor dies 140 are provided and placed on the bonding structure 130, and a bonding process is performed to bond the bonding structures 148 of the semiconductor dies 140 with the underlying bonding structure 130. Conductive through-vias 150 may be formed on the bonding structure 130. The conductive through-vias 150 are electrically connected to the bonding conductors 134 of the bonding structure 130. The details of the semiconductor dies 140 and the conductive through-vias 150 are already described in accompany with FIG. 5, and thus are omitted here.

As illustrated in FIG. 8, an insulating encapsulant 160 is formed on the bonding structure 130 to laterally encapsulate the semiconductor dies 140 and the conductive through-vias 150. Then, a planarization layer 170 and a redistribution circuit structure 180 are formed. The details of the insulating encapsulant 160, the planarization layer 170 and the redistribution circuit structure 180 are already described in accompany with FIG. 6, and thus are omitted here.

As illustrated in FIG. 8, another bonding structure 130′ is formed on the redistribution circuit structure 180. The bonding structure 130′ may include a bonding dielectric layer 132′ and bonding conductors 134′ embedded in the bonding dielectric layer 132'. The material of the bonding dielectric layer 132′ may be or include silicon oxide (SiOₓ, where x>0), silicon nitride (SiNₓ, where x>0), silicon oxynitirde (SiOₓN_{y}, where x>0 and y >0) or other suitable dielectric material, and the bonding conductors 134′ may be or include conductive vias (e.g., copper vias), conductive pads (e.g., copper pads) or combinations thereof. The bonding structure 130′ may be formed by depositing a dielectric material through a chemical vapor deposition (CVD) process (e.g., a plasma enhanced CVD process or other suitable process); patterning the dielectric material to form the bonding dielectric layer 132′ including openings or through holes for revealing the underlying redistribution wirings 184; and filling conductive material in the openings or through holes defined in the bonding dielectric layer 132′ to form the bonding conductors 134′ embedded in the bonding dielectric layer 132'. As illustrated in FIG. 8, the bonding conductors 134′ of the bonding structure 130′ are electrically connected to the semiconductor dies 140 through the redistribution circuit structure 180.

Then, similar process steps for forming the semiconductor dies 140, the conductive through-vias 150, the insulating encapsulant 160, the planarization layer 170 and the redistribution circuit structure 180 are performed to form semiconductor dies 140', conductive through-vias 150', an insulating encapsulant 160', a planarization layer 170′ and a redistribution circuit structure 180′ over the bonding structure 130'. The relationship and details of the semiconductor dies 140', the conductive through-vias 150', the insulating encapsulant 160', the planarization layer 170′ and the redistribution circuit structure 180′ are similar to those of the semiconductor dies 140, the conductive through-vias 150, the insulating encapsulant 160, the planarization layer 170 and the redistribution circuit structure 180, and thus are omitted here.

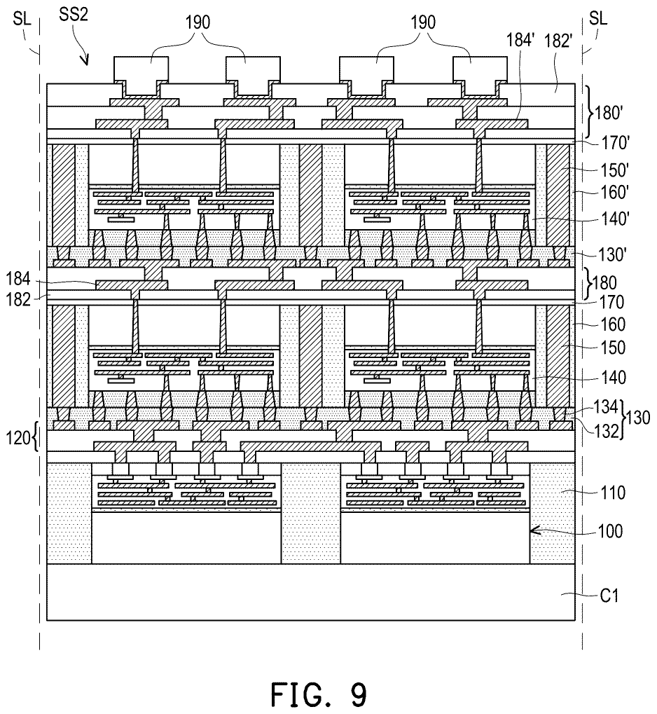

Referring to FIG. 8 and FIG. 9, after forming the redistribution circuit structure 180′ over the semiconductor dies 140', the conductive through-vias 150′ and the insulating encapsulant 160', conductive terminals 190 are formed on the redistribution circuit structure 180′ and electrically connected to the redistribution wirings 184′ of the redistribution circuit structure 180′ through openings defined in the topmost dielectric layer 182'. In some embodiments, the conductive terminals 190 are formed by plating. The plating of the conductive terminals 190 may include forming a blanket seed layer (not shown) over the dielectric layer 182′ and extending into the openings, forming and patterning a photoresist (not shown), and plating the conductive terminals 190 on the portions of the seed layer that are exposed by openings defined in the photoresist. The photoresist and the portions of the seed layer that are covered by the photoresist are then removed. The material of the conductive terminals 190 may include copper, aluminum, or the like. The conductive terminals 190 may have the shape of rods. The top-view shapes of the conductive through-vias 190 may be circles, rectangles, squares, hexagons, or the like. In some embodiments, a reflow process may be performed to re-shape the profile of the conductive terminals 190.

As illustrated in FIG. 9, a singulation process (e.g., a wafer sawing process) is performed along scribe lines SL such that singulated SoIC structures SS2 are obtained. The singulated SoIC structure SS2 shown in FIG. 9 is similar to the singulated SoIC structure SS1 except that the singulated SoIC structure SS2 further includes the bonding structure 130', the semiconductor dies 140', the conductive through-vias 150', the insulating encapsulant 160', the planarization layer 170′ and the redistribution circuit structure 180'. Three tiers of semiconductor dies 100, 140, and 140′ are integrated in the singulated SoIC structure SS2.

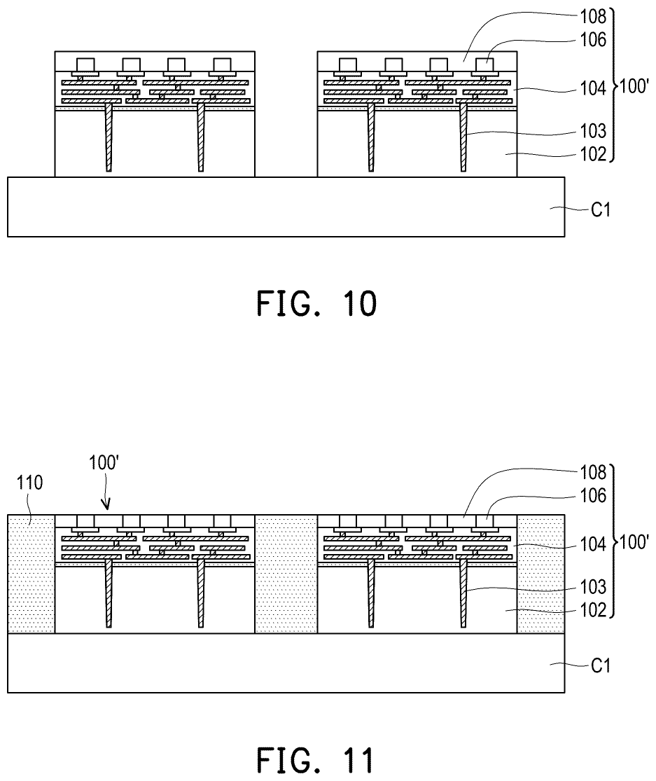

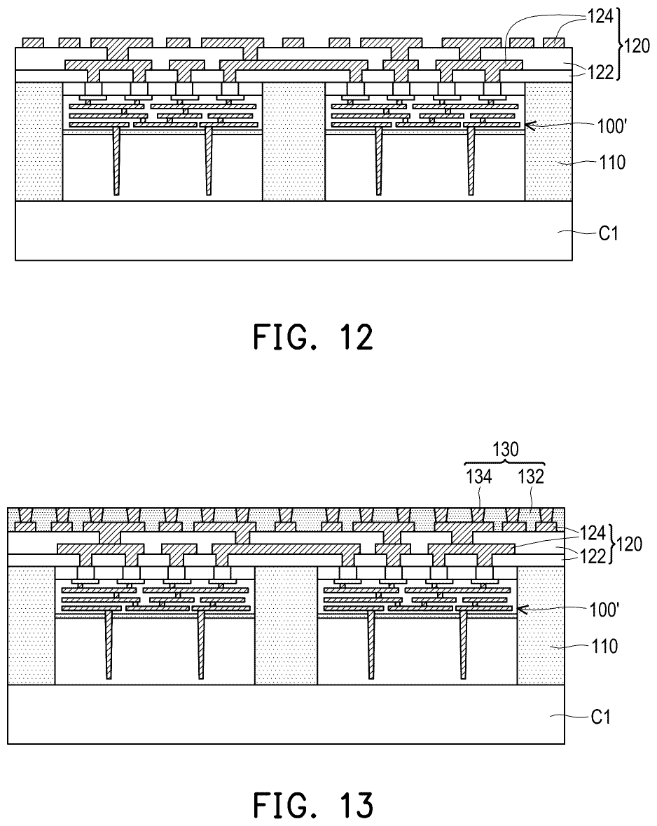

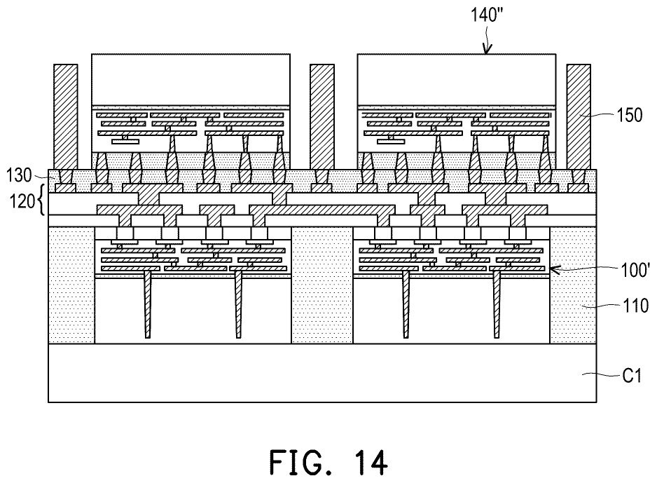

FIGS. 10-17 are cross-sectional views schematically illustrating a process flow for fabricating singulated SoIC structures in accordance with the third embodiment of the present disclosure.

Referring to FIG. 10 through FIG. 14, the process steps illustrated in FIGS. 10 through 14 are similar to those illustrated in FIGS. 1 through 5 except that the first-tier semiconductor dies 100′ includes through semiconductor vias 103, and the second-tier semiconductor dies 140'′ do not include through semiconductor vias. In the semiconductor dies 100', the through semiconductor vias 103 are embedded in the substrate 102, and the through semiconductor vias 103 are electrically connected to the interconnect structure 104.

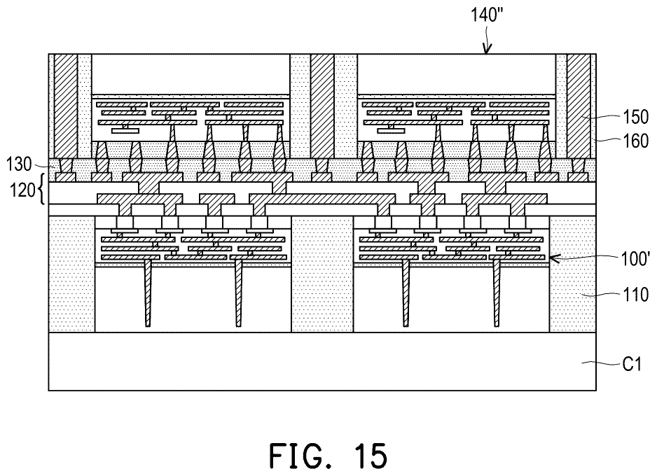

Referring to FIG. 15, an insulating encapsulant 160 is formed on the bonding structure 130 to laterally encapsulate the semiconductor dies 140'′ and the conductive through-vias 150. Then, a planarization layer 170 and a redistribution circuit structure 180 are formed. The details of the insulating encapsulant 160, the planarization layer 170 and the redistribution circuit structure 180 are already described in accompany with FIG. 6, and thus are omitted here.

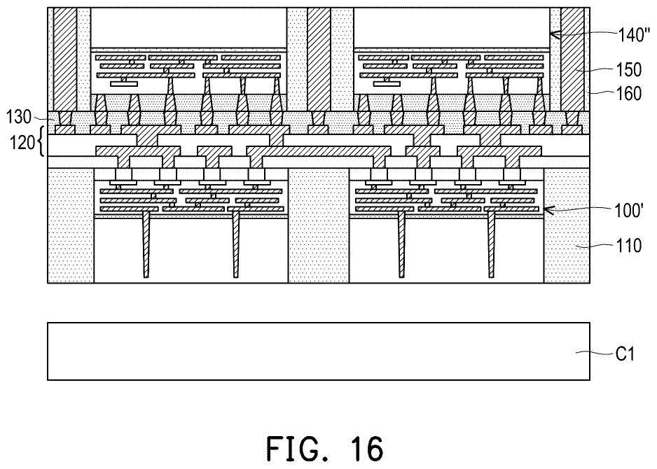

Referring to FIG. 16, a de-bonding process is performed to remove the carrier C1 from the rear surfaces of the semiconductor dies 100′ and the bottom surface of the insulating encapsulant 110 such that the rear surfaces of the semiconductor dies 100′ and the bottom surface of the insulating encapsulant 110 are revealed.

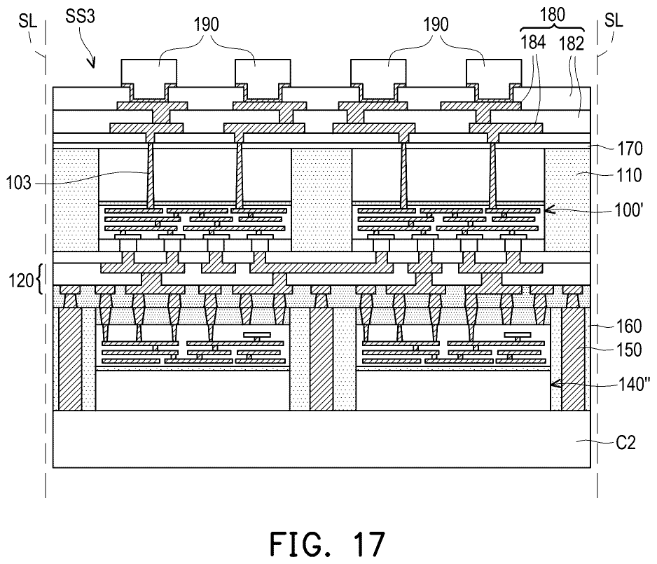

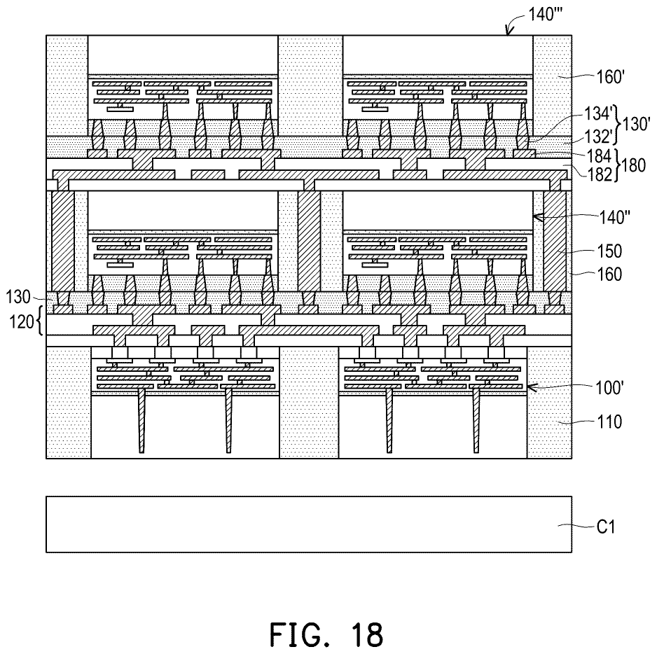

Referring to FIG. 16 and FIG. 17, after performing the de-bonding process of the carrier C1, the resulted structure illustrated in FIG. 16 is flipped upside down and is transfer-bonded to another carrier C2. As illustrated in FIG. 17, the semiconductor dies 140'′ are bonded with and in contact with the carrier C2. The carrier C2 may be a semiconductor wafer, a glass substrate or other suitable substrates.

After the resulted structure illustrated in FIG. 16 is flipped upside down and is transfer-bonded to another carrier C2, a removal process is performed to partially remove the semiconductor dies 100′ and the insulating encapsulant 110 to reveal ends of the through semiconductor vias 103. At this stage, the revealed ends of the through semiconductor vias 103 protrude from the rear surface of the substrate 102. After performing the removal process of the semiconductor dies 100′ and the insulating encapsulant 110, a planarization layer 170 is formed on the rear surface of the substrate 102 to laterally encapsulate sidewalls of the revealed ends of the through semiconductor vias 103. The planarization layer 170 may be formed by a deposition process followed by a CMP process. The planarization layer 170 may be made of silicon nitride or other suitable dielectric materials.

As illustrated in FIG. 17, a redistribution circuit structure 180 including dielectric layers 182 and redistribution wirings 184 embedded in the dielectric layers 182 is formed on the planarization layer 170. In some embodiments, the planarization layer 170 is considered as a part of the redistribution circuit structure 180. The redistribution circuit structure 180 is formed over the rear side of the semiconductor dies 100′ and is electrically connected to the through semiconductor vias 103 of the semiconductor dies 100'.

Referring to FIG. 17, after forming the redistribution circuit structure 180, conductive terminals 190 are formed on the redistribution circuit structure 180 and electrically connected to the redistribution wirings 184 of the redistribution circuit structure 180 through the openings defined in the topmost dielectric layer 182. In some embodiments, the conductive terminals 190 are formed by plating. The plating of the conductive terminals 190 may include forming a blanket seed layer (not shown) over the dielectric layer 182 and extending into the openings, forming and patterning a photoresist (not shown), and plating the conductive terminals 190 on the portions of the seed layer that are exposed by openings defined in the photoresist. The photoresist and the portions of the seed layer that are covered by the photoresist are then removed. The material of the conductive terminals 190 may include copper, aluminum, or the like. The conductive terminals 190 may have the shape of rods. The top-view shapes of the conductive through-vias 190 may be circles, rectangles, squares, hexagons, or the like. In some embodiments, a reflow process may be performed to re-shape the profile of the conductive terminals 190.

As illustrated in FIG. 17, a singulation process (e.g., a wafer sawing process) is performed along scribe lines SL such that singulated SoIC structures SS3 are obtained. The singulated SoIC structure SS3 shown in FIG. 17 includes first-tier semiconductor dies 100', a first insulating encapsulant 110, a first redistribution circuit structure 120, a first bonding structure 130 and second-tier semiconductor dies 140''. The first insulating encapsulant 110 laterally encapsulates the first-tier semiconductor dies 100'. The first redistribution circuit structure 120 and the second redistribution circuit structure 180 are respectively deposited on opposite sides of the first-tier semiconductor dies 100'. No bonding process is required to electrically connected the first-tier semiconductor dies 100′ to the first redistribution circuit structure 120 and the second redistribution circuit structure 180. Accordingly, process yields can be improved.

The first-tier semiconductor dies 100′ may communicate with each other by the first redistribution circuit structure 120 and the second redistribution circuit structure 180, and the second-tier semiconductor dies 140'′ may communicate with each other by the first redistribution circuit structure 120, the first bonding structure 130 and the second redistribution circuit structure 180. Furthermore, the first-tier semiconductor dies 100′ may communicate with the second-tier semiconductor dies 140'′ by the first redistribution circuit structure 120 and the first bonding structure 130. Electrical connection and communication between every semiconductor dies (i.e., the first-tier semiconductor dies 100′ and the second-tier semiconductor dies 140'') in the SoIC structure SS3 can be achieved at least by the first redistribution circuit structure 120 and the first bonding structure 130.

FIGS. 10-15 and FIGS. 18-19 are cross-sectional views schematically illustrating a process flow for fabricating singulated SoIC structures in accordance with the fourth embodiment of the present disclosure.

Referring to FIG. 15 and FIG. 18, after forming the insulating encapsulant 160 as shown in FIG. 15, a redistribution circuit structure 180 including dielectric layers 182 and redistribution wirings 184 embedded in the dielectric layers 182 is formed on the semiconductor dies 140'′ and the insulating encapsulant 160. The redistribution circuit structure 180 is deposited over the semiconductor dies 140'', the conductive through-vias 150 and the insulating encapsulant 160. The redistribution wirings 184 are electrically connected to the underlying conductive through-vias 150.

Another bonding structure 130′ is formed on the redistribution circuit structure 180. The bonding structure 130′ may include a bonding dielectric layer 132′ and bonding conductors 134′ embedded in the bonding dielectric layer 132'. The material of the bonding dielectric layer 132′ may be or include silicon oxide (SiOₓ, where x>0), silicon nitride (SiNₓ, where x>0), silicon oxynitirde (SiOₓN_{y}, where x>0 and y >0) or other suitable dielectric material, and the bonding conductors 134′ may be or include conductive vias (e.g., copper vias), conductive pads (e.g., copper pads) or combinations thereof. The bonding structure 130′ may be formed by depositing a dielectric material through a chemical vapor deposition (CVD) process (e.g., a plasma enhanced CVD process or other suitable process); patterning the dielectric material to form the bonding dielectric layer 132′ including openings or through holes for revealing the underlying redistribution wirings 184; and filling conductive material in the openings or through holes defined in the bonding dielectric layer 132′ to form the bonding conductors 134′ embedded in the bonding dielectric layer 132'. As illustrated in FIG. 18, the bonding conductors 134′ of the bonding structure 130′ are electrically connected to the semiconductor dies 140'′ through the redistribution circuit structure 180.

Then, similar process steps for forming the insulating encapsulant 160 are performed to form an insulating encapsulant 160′ over the bonding structure 130′ to laterally encapsulate the semiconductor dies 140''.

Referring to FIG. 18, a de-bonding process is performed to remove the carrier C1 from the rear surfaces of the semiconductor dies 100′ and the bottom surface of the insulating encapsulant 110 such that the rear surfaces of the semiconductor dies 100′ and the bottom surface of the insulating encapsulant 110 are revealed.

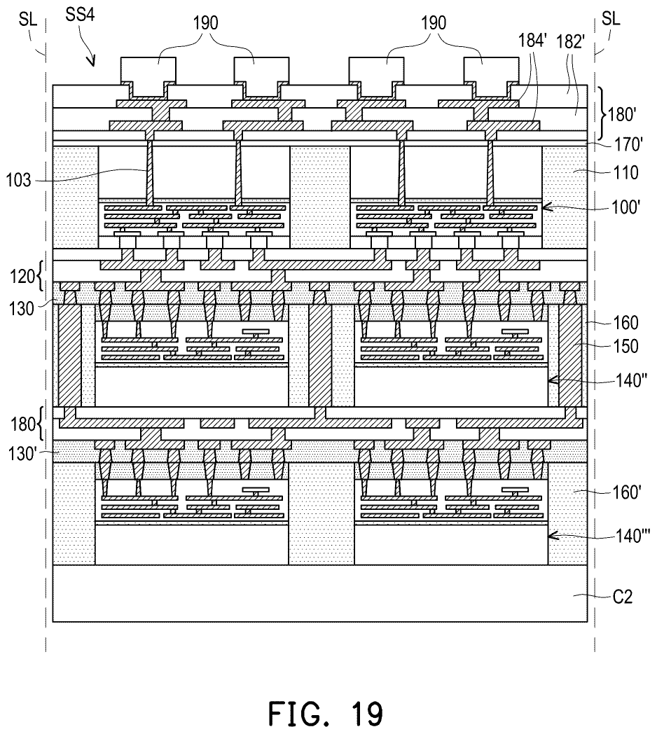

Referring to FIG. 18 and FIG. 19, after performing the de-bonding process of the carrier C1, the resulted structure illustrated in FIG. 18 is flipped upside down and is transfer-bonded to another carrier C2. As illustrated in FIG. 19, the third-tier semiconductor dies 140''′ are bonded with and in contact with the carrier C2. The carrier C2 may be a semiconductor wafer, a glass substrate or other suitable substrates.

After the resulted structure illustrated in FIG. 18 is flipped upside down and is transfer-bonded to another carrier C2, a removal process is performed to partially remove the semiconductor dies 100′ and the insulating encapsulant 110 to reveal ends of the through semiconductor vias 103. At this stage, the revealed ends of the through semiconductor vias 103 protrude from the rear surface of the substrate 102. After performing the removal process of the semiconductor dies 100′ and the insulating encapsulant 110, a planarization layer 170′ is formed on the rear surface of the substrate 102 to laterally encapsulate sidewalls of the revealed ends of the through semiconductor vias 103. The planarization layer 170′ may be formed by a deposition process followed by a CMP process. The planarization layer 170′ may be made of silicon nitride or other suitable dielectric materials.

As illustrated in FIG. 19, a redistribution circuit structure 180′ including dielectric layers 182′ and redistribution wirings 184′ embedded in the dielectric layers 182′ is formed on the planarization layer 170'. In some embodiments, the planarization layer 170′ is considered as a part of the redistribution circuit structure 180'. The redistribution circuit structure 180′ is formed over the rear side of the semiconductor dies 100′ and is electrically connected to the through semiconductor vias 103 of the semiconductor dies 100'.

Referring to FIG. 19, after forming the redistribution circuit structure 180', conductive terminals 190 are formed on the redistribution circuit structure 180′ and electrically connected to the redistribution wirings 184′ of the redistribution circuit structure 180′ through the openings defined in the topmost dielectric layer 182'. In some embodiments, the conductive terminals 190 are formed by plating. The plating of the conductive terminals 190 may include forming a blanket seed layer (not shown) over the dielectric layer 182′ and extending into the openings, forming and patterning a photoresist (not shown), and plating the conductive terminals 190 on the portions of the seed layer that are exposed by openings defined in the photoresist. The photoresist and the portions of the seed layer that are covered by the photoresist are then removed. The material of the conductive terminals 190 may include copper, aluminum, or the like. The conductive terminals 190 may have the shape of rods. The top-view shapes of the conductive through-vias 190 may be circles, rectangles, squares, hexagons, or the like. In some embodiments, a reflow process may be performed to re-shape the profile of the conductive terminals 190.

As illustrated in FIG. 19, a singulation process (e.g., a wafer sawing process) is performed along scribe lines SL such that singulated SoIC structures SS4 are obtained. The singulated SoIC structure SS4 shown in FIG. 19 includes semiconductor dies 100', a first insulating encapsulant 110, a first redistribution circuit structure 120, a first bonding structure 130, semiconductor dies 140'', a second insulating encapsulant 160, a second redistribution circuit structure 180, a second bonding structure 130', semiconductor dies 140''′ and a third insulating encapsulant 160'. The first insulating encapsulant 110 laterally encapsulates the semiconductor dies 100'. The second insulating encapsulant 160 laterally encapsulates the semiconductor dies 140''. The third insulating encapsulant 160′ laterally encapsulates the semiconductor dies 140'''. The first redistribution circuit structure 120 and the first bonding structure 130 are disposed between the semiconductor dies 100′ and the semiconductor dies 140''. The second redistribution circuit structure 180 and the second bonding structure 130′ are disposed between the semiconductor dies 140'′ and the semiconductor dies 140'''. The first redistribution circuit structure 120 and the second redistribution circuit structure 180′ are respectively deposited on opposite sides of the semiconductor dies 100'. No bonding process is required to electrically connected the semiconductor dies 100′ to the first redistribution circuit structure 120 and the second redistribution circuit structure 180'. Accordingly, process yields can be improved.

The semiconductor dies 100′ may communicate with each other by the first redistribution circuit structure 120 and the third redistribution circuit structure 180', the semiconductor dies 140'′ may communicate with each other by the first redistribution circuit structure 120 and the first bonding structure 130, and the semiconductor dies 140''′ may communicate with each other by the second redistribution circuit structure 180. Furthermore, the semiconductor dies 100′ may communicate with the semiconductor dies 140'′ by the first redistribution circuit structure 120 and the first bonding structure 130, and the semiconductor dies 140'′ may communicate with the semiconductor dies 140''′ by the second redistribution circuit structure 180 and the second bonding structure 130'. Electrical connection and communication between every semiconductor dies (i.e., the semiconductor dies 100', 140'′ and 140''') in the SoIC structure SS4 can be achieved at least by the first redistribution circuit structure 120, the first bonding structure 130, the second bonding structure 130', the conductive through-vias 150, and the second redistribution circuit structure 180.

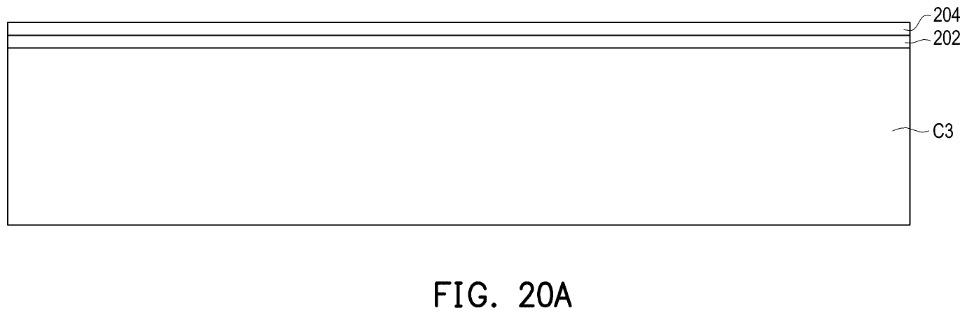

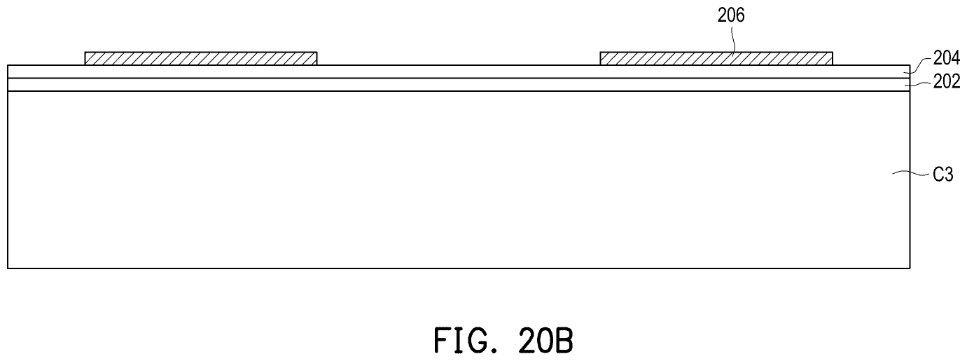

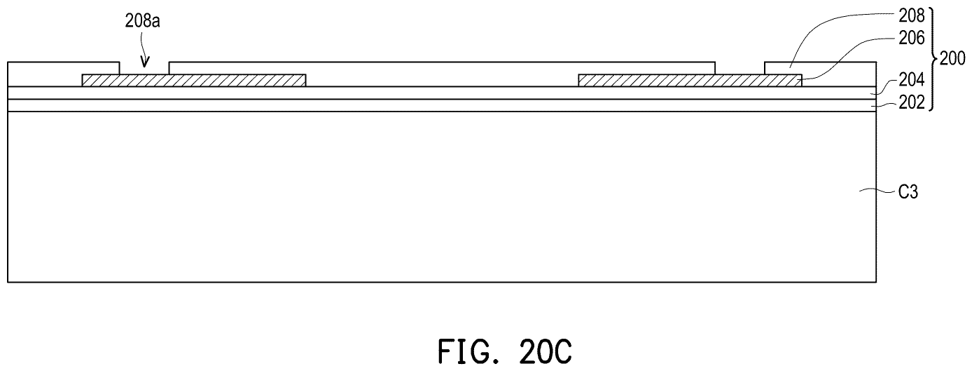

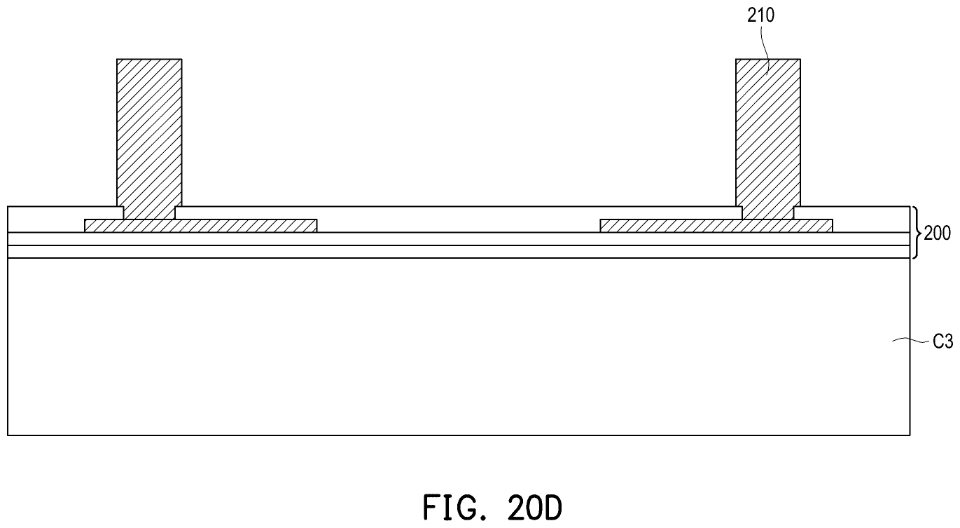

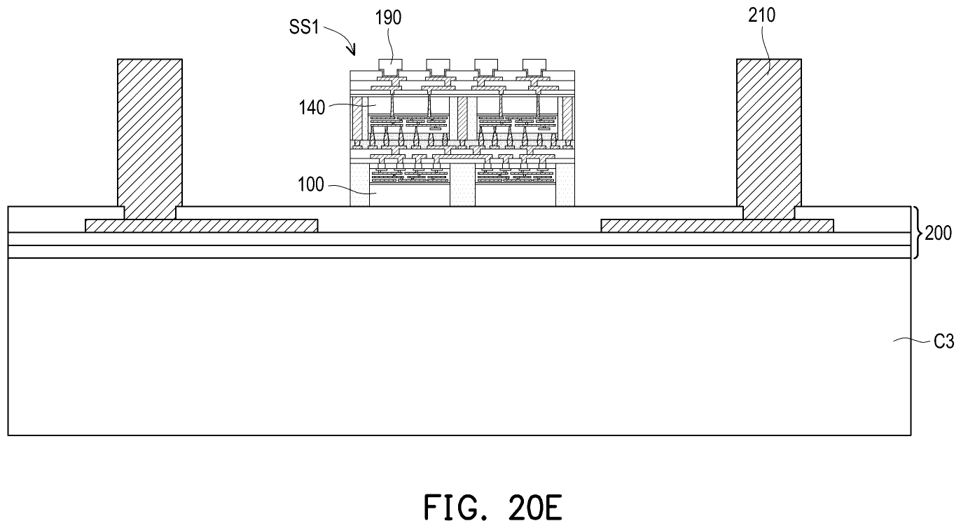

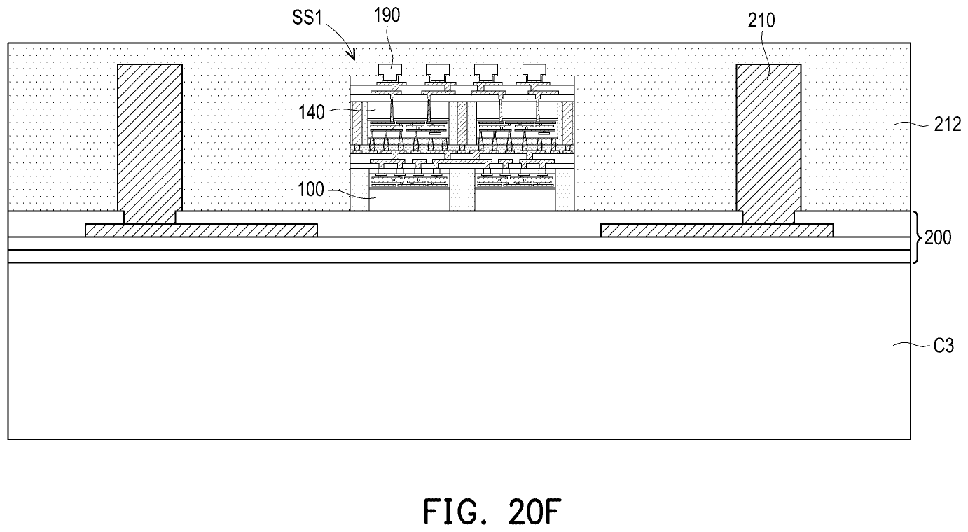

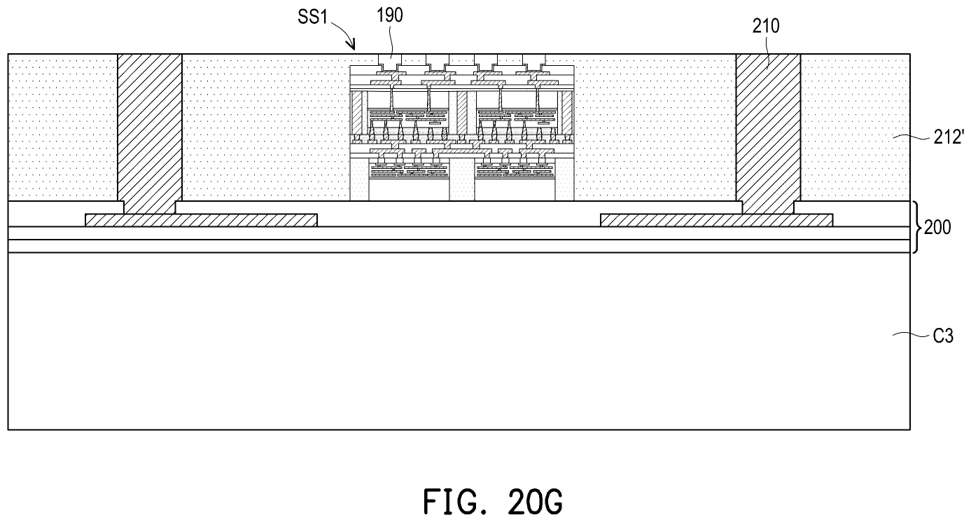

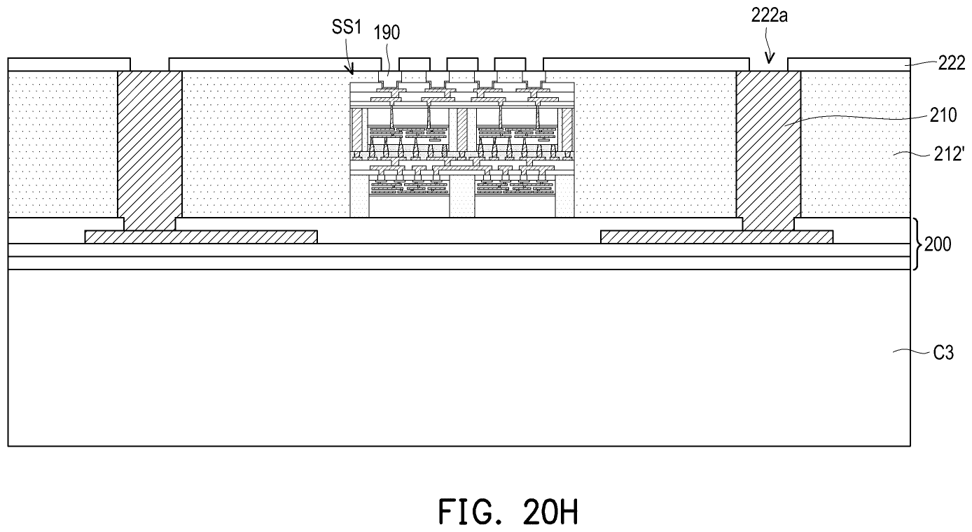

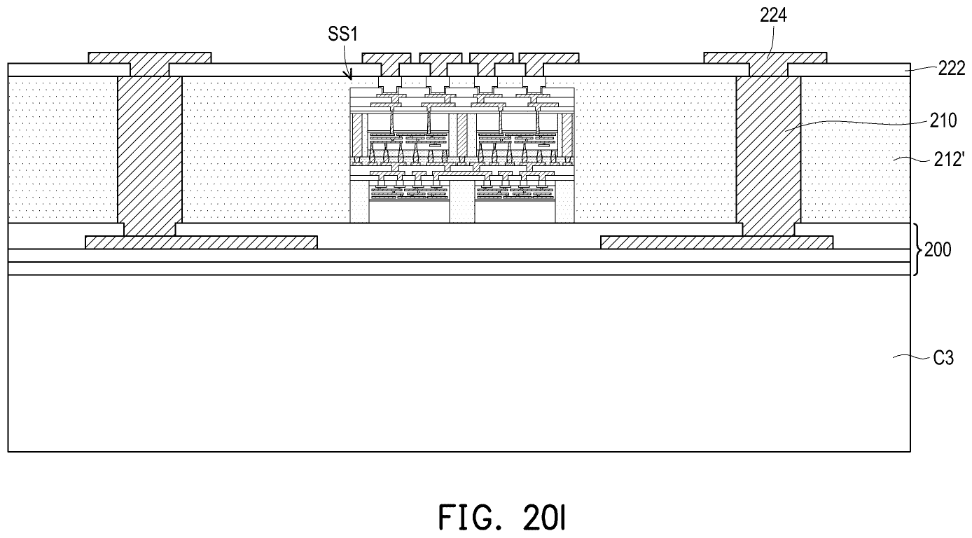

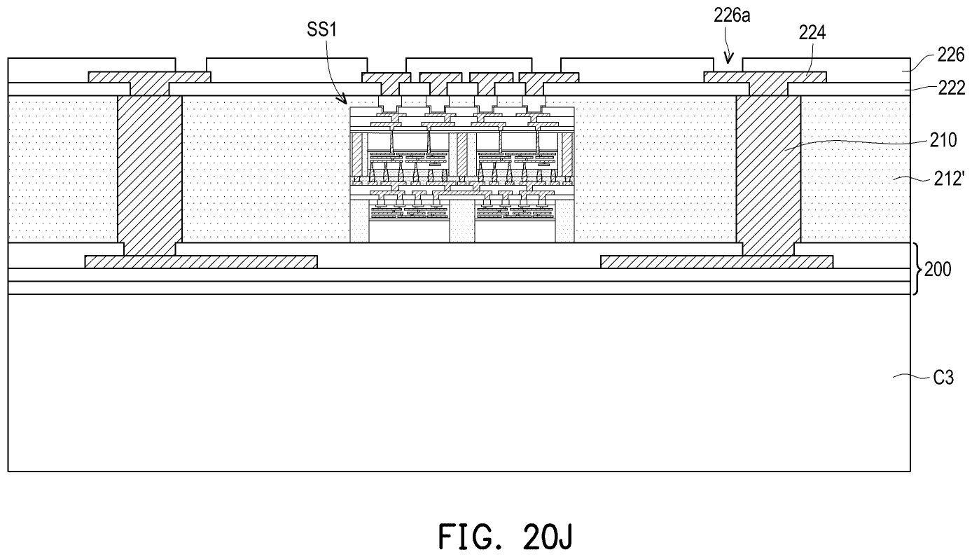

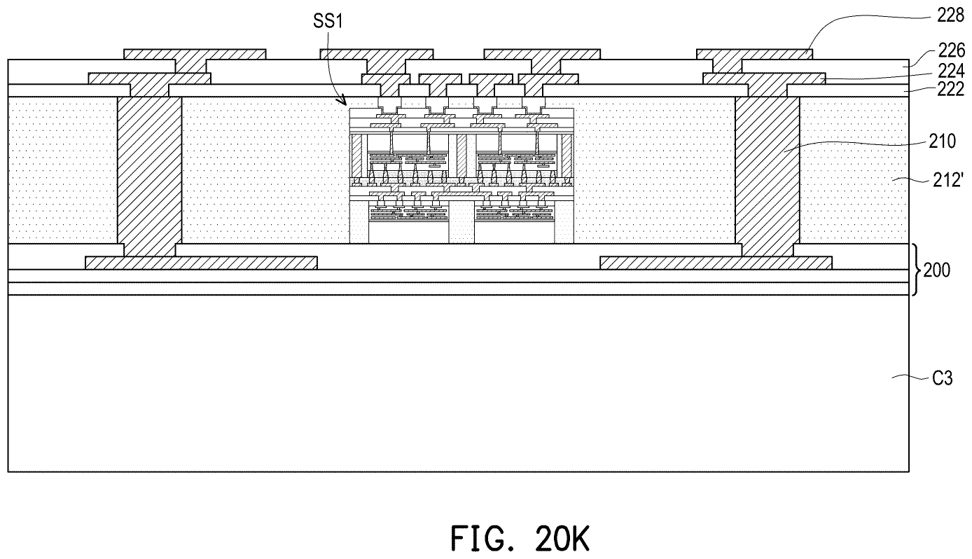

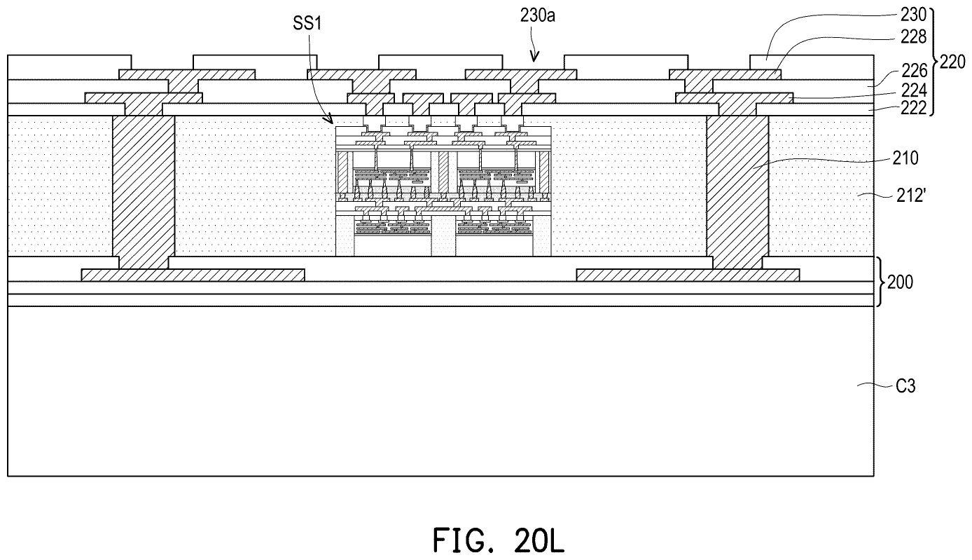

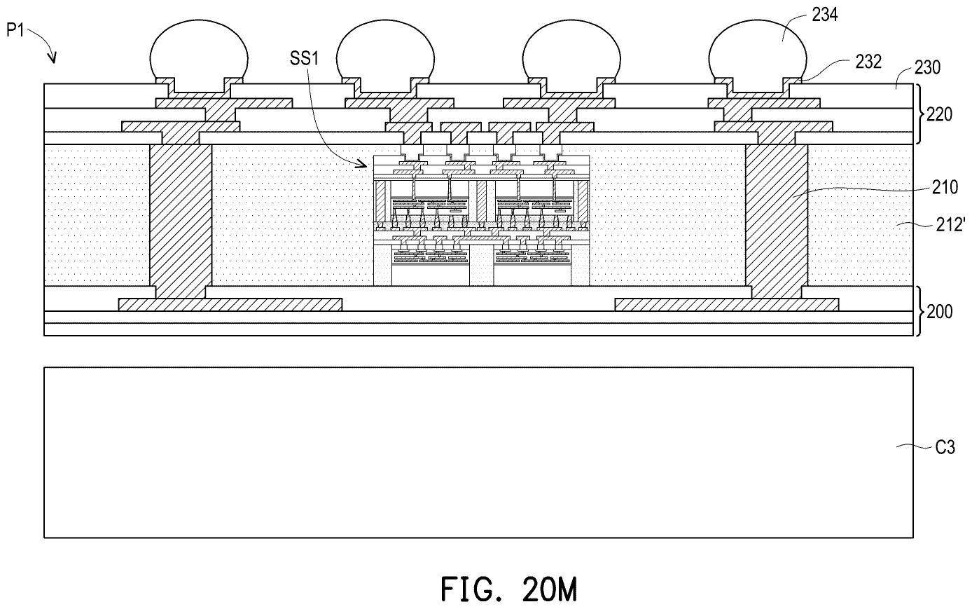

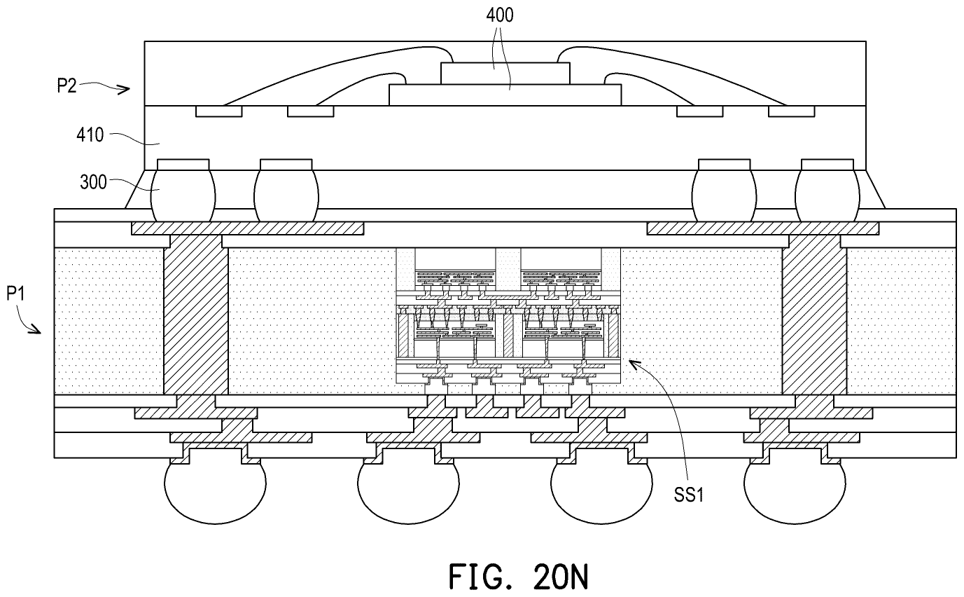

FIGS. 20A through 20N are cross-sectional views schematically illustrating a process flow for fabricating integrated fan-out package structures of the SoIC structure shown in FIG. 7 in accordance with some embodiments of the present disclosure. FIGS. 20A through 20N illustrate the packaging process of the SoIC structure SS1 illustrated in FIG. 7 to fabricate an InFO package structure, so that the overlying electrical connectors (such as solder regions) may be distributed to regions larger than the SoIC structure SS1.

Referring to FIG. 20A, a carrier C3 including a de-bonding layer 202 formed thereon is provided. In some embodiments, the carrier C3 is a glass substrate, a ceramic carrier, or the like. The carrier C3 may have a round top-view shape and a size of a silicon wafer. For example, carrier C3 may have an 8-inch diameter, a 12- inch diameter, or the like. The de-bonding layer 202 may be formed of a polymer-based material (e.g., a Light-To-Heat-Conversion (LTHC) material), which may be subsequently removed along with the carrier C3 from the overlying structures that will be formed in subsequent steps. In some embodiments, the de-bonding layer 202 is formed of an epoxy-based thermal-release material. In other embodiments, the de-bonding layer 202 is formed of an ultra-violet (UV) glue. The de-bonding layer 202 may be dispensed as a liquid and cured. In alternative embodiments, the de-bonding layer 202 is a laminate film and is laminated onto the carrier C3. The top surface of the de-bonding layer 202 is substantially planar.

Referring to FIGS. 20A through 20C, a redistribution circuit structure 200 including a dielectric layer 204, redistribution wirings 206 and a dielectric layer 208 is formed on the de-bonding layer 202 such that the de-bonding layer 202 is between the carrier C3 and the dielectric layer 204 of the redistribution circuit structure 200. As shown in FIG. 20A, the dielectric layer 204 is formed on the de-bonding layer 202. In some embodiments, the dielectric layer 204 is formed of a polymer, which may also be a photo-sensitive material such as PBO, polyimide, BCB, or the like, which may be easily patterned using a photolithography process followed by an etch process. In some embodiments, the dielectric layer 204 is formed of a nitride such as silicon nitride, an oxide such as silicon oxide, PSG, BSG, BPSG, or the like. As shown in FIG. 20B, the redistribution wirings 206 are formed over the dielectric layer 204. The formation of the redistribution wirings 206 may include forming a seed layer (not shown) over the dielectric layer 204, forming a patterned mask (not shown) such as a photoresist layer over the seed layer, and then performing a plating process on the exposed seed layer. The patterned mask and the portions of the seed layer covered by the patterned mask are then removed, leaving the redistribution wirings 206 as shown in FIG. 20B. In accordance with some embodiments, the seed layer includes a titanium layer and a copper layer over the titanium layer. The seed layer may be formed using, for example, a PVD process. The plating may be performed using, for example, electroless plating. As shown in FIG. 20C, the dielectric layer 208 is formed over the dielectric layer 204 to cover the redistribution wirings 206. The bottom surface of the dielectric layer 208 is in contact with the top surfaces of the redistribution wirings 206 and the dielectric layer 204. In accordance with some embodiments of the present disclosure, the dielectric layer 208 is formed of a polymer, which may be a photo-sensitive material such as PBO, polyimide, BCB, or the like. In some embodiments, the dielectric layer 208 is formed of a nitride such as silicon nitride, an oxide such as silicon oxide, PSG, BSG, BPSG, or the like. The dielectric layer 208 is then patterned to form openings 208a therein. Hence, portions of the redistribution wirings 206 are exposed through the openings 208a in the dielectric layer 208. FIG. 20C and the subsequent figures illustrate a single redistribution circuit structure 200 having a single layered redistribution wirings 206 for illustrative purposes and some embodiments may have a plurality of layers of redistribution wirings 206 by repeating the process discussed above.

Referring to FIG. 20D, after forming the redistribution circuit structure 200 over the de-bonding layer 202 carried by the carrier C3, metal posts 210 are formed on the redistribution circuit structure 200 and electrically connected to the redistribution wirings 206 of the redistribution circuit structure 200. Throughout the description, the metal posts 210 are alternatively referred to as conductive through-vias 210 since the metal posts 210 penetrate through the subsequently formed molding material (shown in FIG. 2G). In some embodiments, the conductive through-vias 210 are formed by plating. The plating of the conductive through-vias 210 may include forming a blanket seed layer (not shown) over the dielectric layer 208 and extending into the openings 208a shown in FIG. 20C, forming and patterning a photoresist (not shown), and plating the conductive through-vias 210 on the portions of the seed layer that are exposed through the openings in the photoresist. The photoresist and the portions of the seed layer that were covered by the photoresist are then removed. The material of the conductive through-vias 210 may include copper, aluminum, or the like. The conductive through-vias 210 may have the shape of rods. The top-view shapes of the conductive through-vias 210 may be circles, rectangles, squares, hexagons, or the like.

Referring FIG. 20E, after forming the conductive through-vias 210, at least one singulated SoIC structure, for example, the singulated SoIC structure SS1 shown in FIG. 7, is picked-up and placed over the dielectric layer 208 of the redistribution circuit structure 200. Only a single singulated SoIC structure SS1 and its surrounding conductive through-vias 210 are illustrated in FIG. 20E for illustrative purposes. It is noted, however, that the process steps shown in FIGS. 20A through 20N may be performed at wafer level, and may be performed on all of the singulated SoIC structures SS1 and the conductive through-vias 210 carried by the carrier C3. As illustrated in FIG. 20E, after the singulated SoIC structures SS1 is mounted on the redistribution circuit structure 200, the semiconductor dies 140 are located over the semiconductor dies 100, and the rear surface of the semiconductor dies 100 in the singulated SoIC structure SS1 is adhered to the dielectric layer 208 through a die-attachment film. The die-attachment film may be an adhesive film (e.g., an epoxy film, a silicone film, other suitable adhesive layer or combinations thereof).

Referring to FIG. 20F, an insulating encapsulation material 212 is formed over the redistribution circuit structure 200 to cover the SoIC structure SS1 and the conductive through-vias 210. The insulating encapsulation material 212 may be a molding compound (e.g., epoxy or other suitable resin) formed through an over-molding process. The insulating encapsulation material 212 fills the gaps between the conductive through-vias 210 and the SoIC structure SS1. The top surface of the insulating encapsulation material 212 is higher than the rear surface of the SoIC structure SS1 and the conductive through-vias 210.

Next, as shown in FIG. 20G, a planarization such as a CMP process and/or a mechanical grinding process is performed to partially remove the insulating encapsulation material 212 until the conductive through-vias 210, the conductive terminals 190 of the SoIC structure SS1 are exposed. After the insulating encapsulation material 212 is thinned down, an insulating encapsulant 212′ is formed to laterally encapsulate the SoIC structure SS1 and the conductive through-vias 210. Due to the planarization, the top ends of conductive through-vias 210 substantially level with the top ends of the conductive terminals 190, and substantially level with the top surface of the insulating encapsulant 212', within process variations. In the illustrated exemplary embodiments, the planarization is performed until the conductive through-vias 210 and the conductive terminals 190 are exposed. As shown in FIG. 20G, the insulating encapsulant 212′ may fill the gaps between the conductive terminals 190. Furthermore, the thickness of the insulating encapsulant 212′ is substantially equal to that of the SoIC structure SS1.

FIGS. 20H through 20M illustrate formation of a redistribution circuit structure 220 and solder regions. As shown in FIGS. 20H through 20L, the redistribution circuit structure 220 including a dielectric layer 222, redistribution wirings 224, a dielectric layer 226, redistribution wirings 228, and a dielectric layer 230 is formed on the conductive terminals 190 of the SoIC structure SS1 as well as the insulating encapsulant 212'. As shown in FIG. 20M, solder regions including Under-Bump Metallurgies (UBMs) 232 and electrical connectors 234 disposed on the UBMs 232 are formed on the redistribution circuit

### Structure 220.

Referring to FIG. 20H, a dielectric layer 222 is formed on the conductive terminals 190 of the SoIC structure SS1 and the insulating encapsulant 212'. In some embodiments, the dielectric layer 222 is formed of a polymer such as PBO, polyimide, or the like. In some embodiments, dielectric layer 222 is formed of silicon nitride, silicon oxide, or the like. Openings 222a are formed in the dielectric layer 222 to expose conductive through-vias 210 and the conductive terminals 190. The formation of the openings 222 a may be performed through a photolithography process followed by an etch process.

Next, referring to FIG. 20I, redistribution wirings 224 are formed on the dielectric layer 22 to electrically connect to the conductive terminals 190 and the conductive through-vias 210. The redistribution wirings 224 may include metal traces (metal lines) over the dielectric layer 222 as well as metal vias extending into the openings 222a (shown in FIG. 20H) to electrically connect to the conductive through-vias 210 and the conductive terminals 190. In some embodiments, the redistribution wirings 224 are formed by a plating process, wherein each of the redistribution wirings 224 includes a seed layer (not shown) and a plated metallic material over the seed layer. The seed layer and the plated material may be formed of the same material or different materials. The redistribution wirings 224 may include a metal or a metal alloy including aluminum, copper, tungsten, and alloys thereof. The redistribution wirings 224 are formed of non-solder materials. The via portions of the redistribution wirings 224 may be in physical contact with the top surfaces of the conductive terminals 190 and the conductive through-vias 210.

Referring to FIG. 20J, a dielectric layer 226 is formed over the redistribution wirings 224 and the dielectric layer 222. The dielectric layer 226 may be formed using a polymer, which may be selected from the same candidate materials as those of the dielectric layer 222. For example, the dielectric layer 226 may include PBO, polyimide, BCB, or the like. In some embodiments, the dielectric layer 226 may include non-organic dielectric materials such as silicon oxide, silicon nitride, silicon carbide, silicon oxynitride, or the like. Openings 226a are also formed in the dielectric layer 226 to expose the redistribution wirings 224. The formation of the openings 226a may be performed through a photolithography process followed by an etch process.

Referring to FIG. 20K, FIG. 20K illustrates the formation of redistribution wirings 228, which are electrically connected to the redistribution wirings 224. The formation of the redistribution wirings 228 may adopt similar methods and materials to those for forming the redistribution wirings 224.

Referring to FIG. 20L, an additional dielectric layer 230, which may be a polymer layer, is formed to cover the redistribution wirings 228 and the dielectric layer 226. The dielectric layer 230 may be selected from the same candidate polymers used for forming the dielectric layers 222 and 226. Openings 230a are then formed in the dielectric layer 230 to expose the metal pad portions of redistribution wirings 228. The formation of the openings 230a may be performed through a photolithography process followed by an etch process.

FIG. 20M illustrates the formation of the UBMs 232 and the electrical connectors 234 in accordance with some exemplary embodiments. Referring to FIG. 20M, the formation of the UBMs 232 may include a deposition process followed by a patterning process. The formation of the electrical connectors 234 may include placing solder on the exposed portions of the UBMs 232 and then reflowing the solder to form solder balls. In some embodiments, the formation of the electrical connectors 234 includes performing a plating step to form solder regions over redistribution wirings 228 and then reflowing the solder regions. The electrical connectors 234 may also include metal pillars or metal pillars and solder caps, which may also be formed through plating. Throughout the description, the combined structure including the SoIC structure SS1, the conductive through-vias 210, the insulating encapsulant 212', the redistribution circuit structures 200, the redistribution circuit structures 220, the UBMs 232, and the electrical connectors 234 will be referred to as a package P1, which may be a composite wafer with a round top-view shape.

Next, the package P1 is de-bonded from carrier C3. The de-bonding layer 202 is also cleaned from the package P1. The de-bonding may be performed by irradiating a light such as UV light or laser on the de-bonding layer 202 to decompose the de-bonding layer 202. In the de-bonding process, a tape (not shown) may be adhered onto the dielectric layer 230 and the electrical connectors 234. In subsequent steps, the carrier C3 and the de-bonding layer 202 are removed from the package P1. A sawing process is performed to saw the package P1 into multiple Integrated Fan-out (InFO) package packages, each including at least one SoIC structure SS1, conductive through-vias 210, an insulating encapsulant 212', a redistribution circuit structures 200, a redistribution circuit structures 230, the UBMs 232, and the electrical connectors 234. One of the resulting packages is shown as a package structure P1 illustrated in FIG. 20M.

FIG. 20N illustrates a package on package (PoP) structure in accordance with some embodiments of the present disclosure. Referring to FIG. 20N, another package P2 is provided and bonded with the package P1 such that a PoP structure is formed. In some embodiments of the present disclosure, the bonding between the package P2 and the package P1 is performed through solder regions 300, which joins the metal pad portions of the redistribution wirings 206 to the metal pads in the package P2. In some embodiments, the package P2 includes device dies 400 carried by a package substrate 410, wherein the device dies 400 may be memory dies such as Static Random Access Memory (SRAM) dies, Dynamic Random Access Memory (DRAM) dies, or the like. The memory dies may be bonded to and electrically connected to the package substrate 410 in some exemplary embodiments.

In some alternative embodiments, the SoIC structures SS2 illustrated in FIG. 9, SS3 illustrated in FIG. 17 and SS4 illustrated in FIG. 19 may be applied in the process shown in FIGS. 20E through 20M.

In accordance with some embodiments of the disclosure, a system on integrated circuit (SoIC) structure is provided. The SoIC includes first semiconductor dies, a first insulating encapsulant, a first redistribution circuit structure, a first bonding structure and a second semiconductor die. The first insulating encapsulant laterally encapsulates the first semiconductor dies. The first redistribution circuit structure is disposed on the first semiconductor dies and the first insulating encapsulant. The first bonding structure is disposed on and electrically connected to the first redistribution circuit structure, wherein the first bonding structure includes a first bonding dielectric layer and first bonding conductors embedded in the first bonding dielectric layer. The second semiconductor die includes a second bonding structure, the second bonding structure includes a second bonding dielectric layer and second bonding conductors embedded in the second bonding dielectric layer, wherein the first bonding dielectric layer is bonded with the second bonding dielectric layer, and the first bonding conductors are electrically connected to the second bonding conductors. In some embodiments, sidewalls of the first insulating encapsulant substantially align with sidewalls of the first bonding structure. In some embodiments, sidewalls of the first insulating encapsulant substantially align with sidewalls of the first redistribution circuit structure. In some embodiments, sidewalls of the first insulating encapsulant substantially align with sidewalls of the first bonding structure and sidewalls of the first redistribution circuit structure. In some embodiments, the first bonding structure is between the first redistribution circuit structure and the second semiconductor die. In some embodiments, the SoIC structure further includes a second insulating encapsulant and a second redistribution circuit structure, wherein the second insulating encapsulant is disposed on the first bonding structure and laterally encapsulates the second semiconductor die; and wherein the second redistribution circuit structure is disposed on the second semiconductor die and the second insulating encapsulant, and second redistribution circuit structure is electrically connected to the second semiconductor die. In some embodiments, the second semiconductor die includes through semiconductor vias electrically connected to the first redistribution circuit structure and the second redistribution circuit structure. In some embodiments, the SoIC structure further includes a third semiconductor die disposed on and electrically connected to the second redistribution circuit structure.

In accordance with some other embodiments of the disclosure, a system on integrated circuit (SoIC) structure including a first semiconductor die, a first redistribution circuit structure, a bonding structure and a second redistribution circuit structure is provided. The first semiconductor die is laterally encapsulated by a first insulating encapsulant. The bonding structure is disposed on the first redistribution circuit structure, wherein the first redistribution circuit structure is electrically connected to the first semiconductor die through the bonding structure. The second redistribution circuit structure is electrically connected to the first semiconductor die, wherein the first redistribution circuit structure is spaced apart from the first semiconductor die through the bonding structure, and the second redistribution circuit structure is in contact with the first semiconductor die. In some embodiments, the first redistribution circuit structure and the bonding structure are disposed at a first side of the first semiconductor die. In some embodiments, the second redistribution circuit structure is disposed at a second side of the first semiconductor die, the second side is opposite to the first side. In some embodiments, the first redistribution circuit structure and the second redistribution circuit structure are disposed at opposite sides of the first semiconductor die. In some embodiments, the SoIC structure further includes a second semiconductor die laterally encapsulated by a second insulating encapsulant, wherein the first redistribution circuit structure and the bonding structure are disposed between the first semiconductor die and the second semiconductor die. In some embodiments, sidewalls of the first insulating encapsulant substantially align with sidewalls of the second insulating encapsulant. In some embodiments, sidewalls of the bonding structure substantially align with the first insulating encapsulant and sidewalls of the second insulating encapsulant. In some embodiments, the SoIC structure further includes a third semiconductor die disposed on and electrically connected to the second redistribution circuit structure. In some embodiments, the SoIC structure further includes conductive a through-via penetrating through the first insulating encapsulant, wherein the conductive through-via is electrically connected to the first redistribution circuit structure and the second redistribution circuit structure. In some embodiments, the first semiconductor die includes a through semiconductor via electrically connected to the first redistribution circuit structure and the second redistribution circuit structure.

In accordance with some other embodiments of the disclosure, A method for fabricating a SoIC structure is provided. First semiconductor dies arranged side-by-side are laterally encapsulated with a first insulating encapsulant. A redistribution circuit structure is deposited on the first semiconductor dies and the first insulating encapsulant, wherein each one of the first semiconductor dies are electrically connected to each other through the redistribution circuit structure. A first bonding structure is formed on the redistribution circuit structure. Second semiconductor dies arranged side-by-side are placed on the first bonding structure. The second semiconductor dies are bonded with the first bonding structure. The first insulating encapsulant, the redistribution circuit structure and the first bonding structure are singulated to obtain singulated system on integrated circuit (SoIC) structures. In some embodiments, before the first insulating encapsulant, the redistribution circuit structure and the first bonding structure are singulated to obtain the SoIC structures, the second semiconductor dies are laterally encapsulated with a second insulating encapsulant, wherein the second semiconductor dies are electrically connected to each other through the first bonding structure and the redistribution circuit structure, and the second semiconductor dies are electrically connected to the first semiconductor dies through the first bonding structure and the redistribution circuit structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure, comprising:
first semiconductor dies;
a first insulating encapsulant laterally encapsulating the first semiconductor dies;
a first redistribution circuit structure disposed on the first semiconductor dies and the first insulating encapsulant;
a first bonding structure disposed on and electrically connected to the first redistribution circuit structure, wherein the first bonding structure comprises a first bonding dielectric layer and first bonding conductors embedded in the first bonding dielectric layer; and
a second semiconductor die comprising a second bonding structure, the second bonding structure comprising a second bonding dielectric layer and second bonding conductors embedded in the second bonding dielectric layer, wherein the first bonding dielectric layer is bonded with the second bonding dielectric layer, and the first bonding conductors are electrically connected to the second bonding conductors.

2. The structure of claim 1, wherein sidewalls of the first insulating encapsulant substantially align with sidewalls of the first bonding structure.

3. The structure of claim 1, wherein sidewalls of the first insulating encapsulant substantially align with sidewalls of the first redistribution circuit structure.

4. The structure of claim 1, wherein sidewalls of the first insulating encapsulant substantially align with sidewalls of the first bonding structure and sidewalls of the first redistribution circuit structure.

5. The structure of claim 1, wherein the first bonding structure is between the first redistribution circuit structure and the second semiconductor die.

6. The structure of claim 1 further comprising:
a second insulating encapsulant, wherein the second insulating encapsulant is disposed on the first bonding structure and laterally encapsulates the second semiconductor die; and
a second redistribution circuit structure, wherein the second redistribution circuit structure is disposed on the second semiconductor die and the second insulating encapsulant, and second redistribution circuit structure is electrically connected to the second semiconductor die.

7. The SoIC structure of claim 6, wherein the second semiconductor die comprises through semiconductor vias electrically connected to the first redistribution circuit structure and the second redistribution circuit structure.

8. The SoIC structure of claim 6 further comprising a third semiconductor die disposed on and electrically connected to the second redistribution circuit structure.

9. A structure, comprising:
a first semiconductor die laterally encapsulated by a first insulating encapsulant;
a first redistribution circuit structure;
a bonding structure disposed on the first redistribution circuit structure, wherein the first redistribution circuit structure is electrically connected to the first semiconductor die through the bonding structure; and
a second redistribution circuit structure electrically connected to the first semiconductor die, wherein the first redistribution circuit structure is spaced apart from the first semiconductor die through the bonding structure, and the second redistribution circuit structure is in contact with the first semiconductor die.

10. The structure of claim 9, wherein the first redistribution circuit structure and the bonding structure are disposed at a first side of the first semiconductor die.

11. The structure of claim 10, wherein the second redistribution circuit structure is disposed at a second side of the first semiconductor die, the second side is opposite to the first side.

12. The structure of claim 9, wherein the first redistribution circuit structure and the second redistribution circuit structure are disposed at opposite sides of the first semiconductor die.

13. The structure of claim 9 further comprising:
a second semiconductor die laterally encapsulated by a second insulating encapsulant, wherein the first redistribution circuit structure and the bonding structure are disposed between the first semiconductor die and the second semiconductor die.

14. The structure of claim 13, wherein sidewalls of the first insulating encapsulant substantially align with sidewalls of the second insulating encapsulant.

15. The structure of claim 13, wherein sidewalls of the bonding structure substantially align with the first insulating encapsulant and sidewalls of the second insulating encapsulant.

16. The structure of claim 13 further comprising a third semiconductor die disposed on and electrically connected to the second redistribution circuit structure.

17. The structure of claim 9 further comprising conductive a through-via penetrating through the first insulating encapsulant, wherein the conductive through-via is electrically connected to the first redistribution circuit structure and the second redistribution circuit structure.

18. The structure of claim 9, wherein the first semiconductor die comprises a through semiconductor via electrically connected to the first redistribution circuit structure and the second redistribution circuit structure.

19. A method, comprising:
laterally encapsulating first semiconductor dies arranged side-by-side with a first insulating encapsulant;
depositing a redistribution circuit structure on the first semiconductor dies and the first insulating encapsulant, wherein each one of the first semiconductor dies are electrically connected to each other through the redistribution circuit structure;
forming a first bonding structure on the redistribution circuit structure;
placing second semiconductor dies arranged side-by-side on the first bonding structure;
bonding the second semiconductor dies with the first bonding structure; and
singulating the first insulating encapsulant, the redistribution circuit structure and the first bonding structure to obtain singulated structures.

20. The method of claim 19 further comprising:
before singulating the first insulating encapsulant, the redistribution circuit structure and the first bonding structure to obtain the structures, laterally encapsulating the second semiconductor dies with a second insulating encapsulant, wherein the second semiconductor dies are electrically connected to each other through the first bonding structure and the redistribution circuit structure, and the second semiconductor dies are electrically connected to the first semiconductor dies through the first bonding structure and the redistribution circuit structure.
